(19) United States
(12) Patent Application Publication
(10) Pub. No.: US 2024/0055381 A1
(43) Pub. Date: Feb. 15, 2024

(54) SEMICONDUCTOR DEVICE

(71) Applicant: Kioxia Corporation, Tokyo (JP)

(72) Inventors: Hironobu HAMANAKA, Yokkaichi (JP); Ryuji KUBO, Yokkaichi (JP)

(73) Assignee: Kioxia Corporation, Tokyo (JP)

(21) Appl. No.: 18/335,278

(22) Filed: Jun. 15, 2023

(30) Foreign Application Priority Data
Aug. 9, 2022 (JP) 2022-127272

(51) Int. Cl. H01L 23/00; H10B 43/20; H10B 80/00

(52) U.S. Cl. CPC H01L 24/08; H10B 43/20; H10B 80/00; H01L 2224/08145

(57) ABSTRACT

According to an embodiment, a semiconductor device includes a first chip including a substrate and a second chip bonded to the first chip. The second chip includes a first interconnect layer provided with an external connection terminal, a first semiconductor layer in contact with the first interconnect layer, and a conductor extending in a first direction, having an end portion in contact with the first semiconductor layer, and electrically coupled to the first chip.

### CROSS-REFERENCE TO RELATED APPLICATION

This application is based upon and claims the benefit of priority from Japanese Patent Application No. 2022-127272, filed Aug. 9, 2022, the entire contents of which are incorporated herein by reference.

### FIELD

Embodiments described herein relate generally to a semiconductor device.

### BACKGROUND

A NAND flash memory is known as a semiconductor device.

### BRIEF DESCRIPTION OF THE DRAWINGS

FIG. 1 is a block diagram showing an overall configuration of a semiconductor device according to a first embodiment.

FIG. 2 is a circuit diagram of a memory cell array included in the semiconductor device according to the first embodiment.

FIG. 3 is a perspective view showing an outline of a bonded structure of the semiconductor device according to the first embodiment.

FIG. 4 is a plane view of the semiconductor device according to the first embodiment.

FIG. 5 is a cross-sectional view showing an example of a cross-sectional structure of the semiconductor device according to the first embodiment.

FIG. 6 is a plane view showing an example of a planar layout of a conductor in a wall region in the semiconductor device according to the first embodiment.

FIG. 7 is a cross-sectional view showing an example of a cross-sectional structure of a bonding pad in the semiconductor device according to the first embodiment.

FIG. 8 is a cross-sectional view showing an example of a cross-sectional structure of a memory cell array in the semiconductor device according to the first embodiment.

FIG. 9 is a cross-sectional view showing an example of a cross-sectional structure along an XY plane of a memory pillar in the semiconductor device according to the first embodiment.

FIG. 10 shows a plane view and a cross-sectional view of a region E1 shown in FIG. 5.

FIG. 11 is a cross-sectional view of a region E2 shown in FIG. 5.

FIG. 12 is a cross-sectional view showing an example of a manufacturing process of an array chip in the semiconductor device according to the first embodiment.

FIG. 13 is a cross-sectional view showing an example of the manufacturing process of the array chip in the semiconductor device according to the first embodiment.

FIG. 14 is a cross-sectional view showing an example of the manufacturing process of the array chip in the semiconductor device according to the first embodiment.

FIG. 15 is a cross-sectional view showing an example of the manufacturing process of the array chip in the semiconductor device according to the first embodiment.

FIG. 16 is a cross-sectional view showing an example of the manufacturing process of the array chip in the semiconductor device according to the first embodiment.

FIG. 17 is a cross-sectional view showing an example of the manufacturing process of the array chip in the semiconductor device according to the first embodiment.

FIG. 18 is a cross-sectional view showing an example of a manufacturing process of a bonded structure in the semiconductor device according to the first embodiment.

FIG. 19 is a cross-sectional view showing an example of the manufacturing process of the bonded structure in the semiconductor device according to the first embodiment.

FIG. 20 is a cross-sectional view showing an example of the manufacturing process of the bonded structure in the semiconductor device according to the first embodiment.

FIG. 21 is a cross-sectional view showing an example of the manufacturing process of the bonded structure in the semiconductor device according to the first embodiment.

FIG. 22 is a cross-sectional view showing an example of the manufacturing process of the bonded structure in the semiconductor device according to the first embodiment.

FIG. 23 is a cross-sectional view showing an example of a cross-sectional structure of a semiconductor device according to a first modification of the first embodiment.

FIG. 24 is a cross-sectional view showing an example of a cross-sectional structure of a semiconductor device according to a second modification of the first embodiment.

FIG. 25 shows a plane view and a cross-sectional view of a CC connection region in a semiconductor device according to a third modification of the first embodiment.

FIG. 26 is a cross-sectional view showing an example of a cross-sectional structure of a semiconductor device according to a second embodiment.

FIG. 27 shows a plan view and a cross-sectional view of a region E3 shown in FIG. 26.

FIG. 28 is a cross-sectional view showing an example of a manufacturing process of an array chip in the semiconductor device according to the second embodiment.

FIG. 29 is a cross-sectional view showing an example of the manufacturing process of the array chip in the semiconductor device according to the second embodiment.

FIG. 30 is a cross-sectional view showing an example of the manufacturing process of the array chip in the semiconductor device according to the second embodiment.

FIG. 31 is a cross-sectional view showing an example of the manufacturing process of the array chip in the semiconductor device according to the second embodiment.

FIG. 32 is a cross-sectional view showing an example of the manufacturing process of the array chip in the semiconductor device according to the second embodiment.

FIG. 33 is a cross-sectional view showing an example of the manufacturing process of the array chip in the semiconductor device according to the second embodiment.

FIG. 34 is a cross-sectional view showing an example of a manufacturing process of a bonded structure in the semiconductor device according to the second embodiment.

FIG. 35 is a cross-sectional view showing an example of the manufacturing process of the bonded structure in the semiconductor device according to the second embodiment.

FIG. 36 is a cross-sectional view showing an example of the manufacturing process of the bonded structure in the semiconductor device according to the second embodiment.

FIG. 37 is a cross-sectional view showing an example of the manufacturing process of the bonded structure in the semiconductor device according to the second embodiment.

FIG. 38 is a cross-sectional view showing an example of the manufacturing process of the bonded structure in the semiconductor device according to the second embodiment.

FIG. 39 is a cross-sectional view showing an example of a cross-sectional structure of a semiconductor device according to a first modification of the second embodiment.

FIG. 40 shows a plane view and a cross-sectional view of a CC connection region in a semiconductor device according to a second modification of the second embodiment.

### DETAILED DESCRIPTION

In general, according to one embodiment, a semiconductor device includes a first chip including a substrate and a second chip bonded to the first chip. The second chip includes a first interconnect layer provided with an external connection terminal, a first semiconductor layer in contact with the first interconnect layer, and a conductor extending in a first direction, having an end portion in contact with the first semiconductor layer, and electrically coupled to the first chip.

Embodiments will be described below with reference to the accompanying drawings. The description provided hereinafter uses the same reference sign for components having approximately the same function and configuration. A repeat description may be omitted when unnecessary. Each of the embodiments to be described below is to give examples of devices and methods that realize technical ideas of the embodiment. The technical ideas of the embodiment do not limit the materials, shapes, structures, arrangements, etc. of the structural components to the ones to be described below. Various modifications may be made to the technical ideas of the embodiments without departing from the spirit of the invention. The embodiments and modifications are included in the scope of the claimed inventions and their equivalents.

### 1. First Embodiment

A semiconductor device according to a first embodiment will be described. As an example of the semiconductor device, a three-dimensionally stacked NAND flash memory, in which memory cell transistors are three-dimensionally stacked above a semiconductor substrate, will be described below.

### 1.1 Configuration

### 1.1.1 Overall Configuration of Semiconductor Device

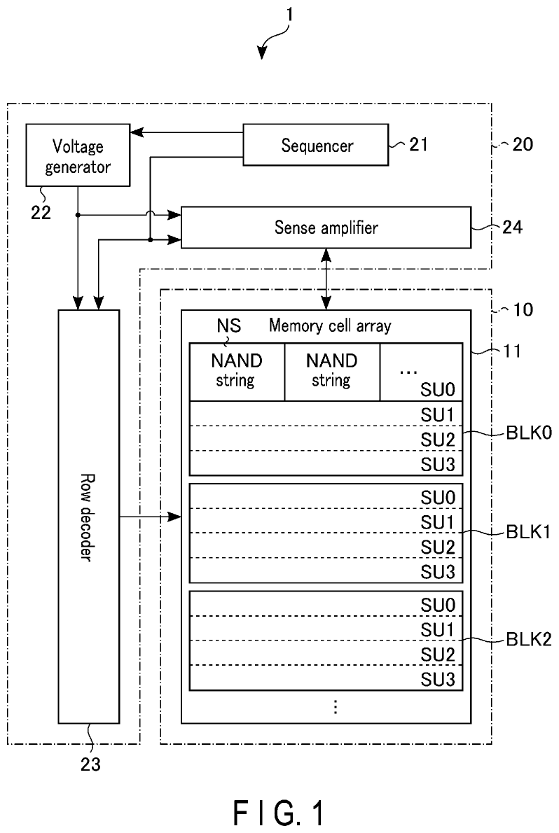

First, an example of an overall configuration of a semiconductor device 1 will be described with reference to FIG. 1. FIG. 1 is a block diagram showing an overall configuration of the semiconductor device 1. In FIG. 1, some of the couplings between the structural elements are indicated by arrows; however, the couplings between the structural elements are not limited thereto.

The semiconductor device 1 is, for example, a three-dimensionally stacked NAND flash memory. The three-dimensionally stacked NAND flash memory includes a plurality of non-volatile memory cell transistors arranged three-dimensionally above a semiconductor substrate.

As shown in FIG. 1, the semiconductor device 1 includes an array chip 10 and a circuit chip 20. The semiconductor device 1 has a structure in which the array chip 10 and the circuit chip 20 are bonded together (hereinafter referred to as a “bonded structure”).

The array chip 10 is a chip in which an array of the non-volatile memory cell transistors is provided. The circuit chip 20 is a chip in which circuits that control the array chip 10 are provided. The semiconductor device 1 according to the present embodiment is formed by bonding the array chip 10 to the circuit chip 20. Hereinafter, the array chip 10 and the circuit chip 20 will each be simply referred to as a “chip” unless otherwise specified. A plurality of array chips 10 may be provided. In such a case, the plurality of array chips 10 may be bonded to the circuit chip 20 in such a manner that the array chips 10 are stacked on the circuit chip 20.

The array chip 10 includes one or more memory cell arrays 11. The memory cell array 11 is a region in which the non-volatile memory cell transistors are arranged three-dimensionally. In the example shown in FIG. 1, the array chip 10 includes one memory cell array 11.

The circuit chip 20 includes a sequencer 21, a voltage generator 22, a row decoder 23, and a sense amplifier 24.

The sequencer 21 is a control circuit of the semiconductor device 1. For example, the sequencer 21 is coupled to the voltage generator 22, the row decoder 23, and the sense amplifier 24. The sequencer 21 then controls the voltage generator 22, the row decoder 23, and the sense amplifier 24. In addition, the sequencer 21 controls the operation of the entire semiconductor device 1 based on control of an external controller. More specifically, the sequencer 21 executes a write operation, a read operation, an erase operation, etc.

The voltage generator 22 is a circuit that generates voltages to be used for the write operation, read operation, erase operation, etc. For example, the voltage generator 22 is coupled to the row decoder 23 and the sense amplifier 24. The voltage generator 22 supplies the generated voltages to the row decoder 23, the sense amplifier 24, etc.

The row decoder 23 is a circuit that decodes a row address. The row address is an address signal for designating interconnects in a row direction in the memory cell array 11. The row decoder 23 supplies the memory cell array 11 with the voltages applied from the voltage generator 22 based on a result of decoding the row address.

The sense amplifier 24 is a circuit that writes and reads data. In a read operation, the sense amplifier 24 senses data read from the memory cell array 11. In a write operation, the sense amplifier 24 supplies the memory cell array 11 with voltages corresponding to write data.

Next, an internal configuration of the memory cell array 11 will be described. The memory cell array 11 includes a plurality of blocks BLK. The block BLK is, for example, a set of a plurality of memory cell transistors whose data is erased in a batch. The plurality of memory cell transistors in the block BLK are respectively associated with rows and columns. In the example shown in FIG. 1, the memory cell array 11 includes blocks BLK0, BLK1, and BLK2.

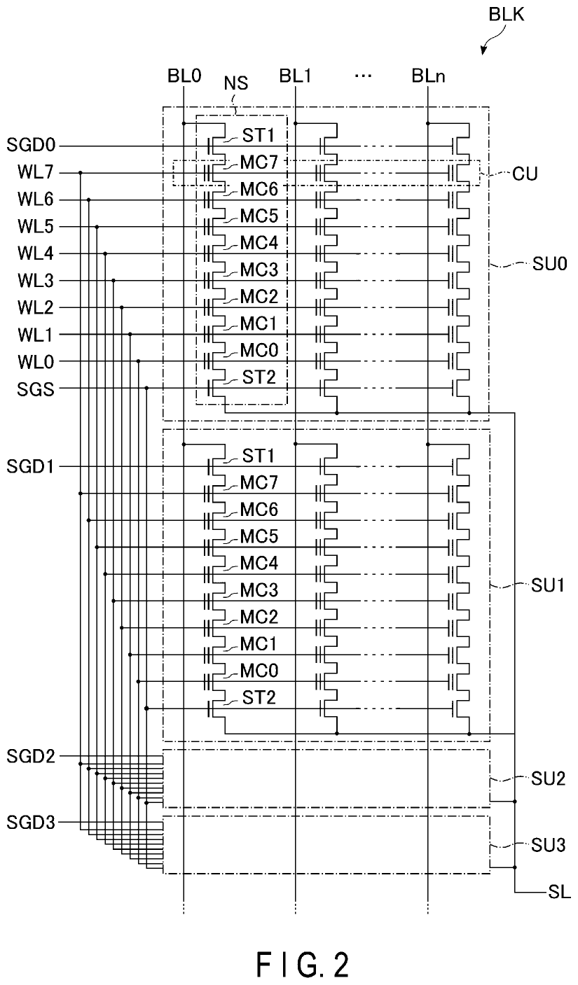

Each block BLK includes a plurality of string units SU. Each string unit SU is, for example, a set of a plurality of NAND strings which are selected in a batch in the write operation or the read operation. Each NAND string includes a set of a plurality of memory cell transistors coupled in series. In the example shown in FIG. 1, each block BLK includes four string units SU0 to SU3. The number of blocks BLK in the memory cell array 11 and the number of string units SU in each of the blocks BLK are freely selected. 1.1.2 Circuit Configuration of Memory Cell Array Next, an example of a circuit configuration of the memory cell array 11 will be described with reference to FIG. 2. FIG. 2 is a circuit diagram of the memory cell array 11. The example in FIG. 2 shows a circuit configuration of one block BLK.

As shown in FIG. 2, each string unit SU includes a plurality of NAND strings NS.

Each of the NAND strings NS includes a plurality of memory cell transistors MC and select transistors ST1 and ST2. In the example shown in FIG. 2, each NAND string NS includes eight memory cell transistors MC0 to MC7. The number of memory cell transistors MC included in the NAND string NS is freely selected.

Each of the memory cell transistors MC is a memory element that stores data in a nonvolatile manner. Each of the memory cell transistors MC includes a control gate and a charge storage film. Each of the memory cell transistors MC may be of a metal-oxide-nitride-oxide-silicon (MONOS) type or may be of a floating gate (FG) type. The MONOS type uses an insulating layer as a charge storage film. The FG type uses a conductor as a charge storage film. Hereinafter, the case in which the memory cell transistors MC are of the MONOS type will be described.

The select transistors ST1 and ST2 are switching elements. The select transistors ST1 and ST2 are respectively used to select a string unit SU in various operations. The number of select transistors ST1 and ST2 included in the NAND string NS is freely selected. It suffices that each NAND string NS contains one or more select transistors ST1 and one or more select transistors ST2.

In each NAND string NS, current paths of the select transistor ST2, the memory cell transistors MC0 to MC7, and the select transistor ST1 are coupled in series. The drain of the select transistor ST1 is coupled to a corresponding bit line BL. The source of the select transistor ST2 is coupled to a source line SL.

The memory cell transistors MC0 to MC7 included in the same block BLK have their control gates coupled in common to word lines WL0 to WL7, respectively. More specifically, for example, the block BLK includes four string units SU0 to SU3. Each string unit SU includes a plurality of memory cell transistors MC0. The plurality of memory cell transistors MC0 in the same block BLK have their control gates coupled in common to the single word line WL0. The same applies to the memory cell transistors MC1 to MC7.

A plurality of select transistors ST1 in a string unit SU have their gates coupled in common to one select gate line SGD. More specifically, the gates of the plurality of select transistors ST1 in the string unit SU0 are coupled in common to a select gate line SGD0. The gates of the plurality of select transistors ST1 in the string unit SU1 are coupled in common to a select gate line SGD1. The gates of the plurality of select transistors ST1 in the string unit SU2 are coupled in common to a select gate line SGD2. The gates of the plurality of select transistors ST1 in the string unit SU3 are coupled in common to a select gate line SGD3.

A plurality of select transistors ST2 in the same block BLK have their gates coupled in common to a select gate line SGS. A different select gate line SGS may be provided for each string unit SU, as with the select gate lines SGD.

The word lines WL0 to WL7, the select gate lines SGD0 to SGD3, and the select gate line SGS are each coupled to the row decoder 23.

Each bit line BL is coupled in common to one NAND string NS included in each string unit SU in each block BLK. The same column address is assigned to a plurality of NAND strings NS coupled to one bit line BL. Each bit line BL is coupled to the sense amplifier 24.

The source line SL is, for example, shared by a plurality of blocks BLK.

A set of a plurality of memory cell transistors MC coupled to a common word line WL in one string unit SU will be referred to as, for example, a “cell unit CU”. For example, write and read operations are executed on a cell unit CU basis.

### 1.1.3 Bonded Structure of Semiconductor Device

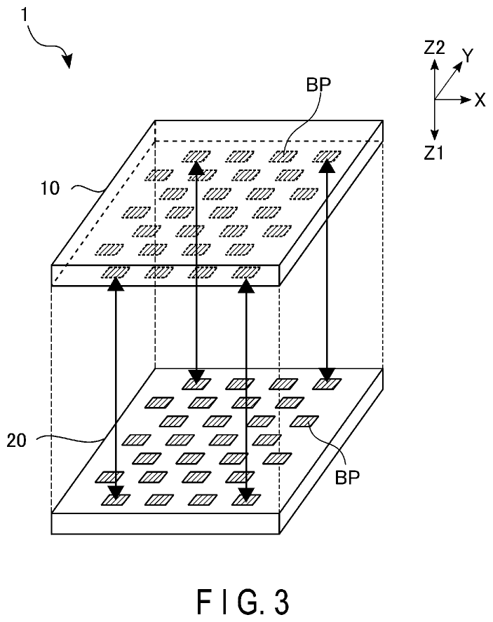

Next, an outline of a bonded structure of the semiconductor device 1 will be described with reference to FIG. 3. FIG. 3 is a perspective view showing an outline of the bonded structure of the semiconductor device 1.

As shown in FIG. 3, each of the array chip 10 and the circuit chip 20 includes a plurality of bonding pads BP provided on the surfaces facing each other. In the bonded structure, each bonding pad BP of the array chip 10 and each bonding pad BP of the circuit chip 20 are bonded to form one bonding pad BP. In other words, each bonding pad BP is formed by bonding an electrode (conductor) constituting a bonding pad BP formed on the array chip 10 to an electrode (conductor) configuring a bonding pad BP formed on the circuit chip 20. The bonding pads BP include an active pad and a dummy pad. The active pad functions as a signal path or a power supply path at the time of activating the semiconductor device 1. That is, the active pad is electrically coupled to either a signal path or a power supply path. The dummy pad does not function as either a signal path or a power supply path at the time of activating the semiconductor device 1. That is, the dummy pad is not electrically coupled to either a signal path or a power supply path.

Hereinafter, the surface on which the array chip 10 and the circuit chip 20 are bonded together (hereinafter referred to as a “bonding surface”) will be referred to as an XY plane. Within the XY plane, two directions orthogonal to each other will be referred to as an “X direction” and a “Y direction”. Furthermore, a direction that is substantially perpendicular to the XY plane and extends from the array chip 10 to the circuit chip 20 will be referred to as a “Z1 direction”. A direction that is substantially perpendicular to the XY plane and extends from the circuit chip 20 to the array chip 10 will be referred to as a “Z2” direction. The Z1 direction and the Z2 direction will each be referred to as a Z direction when they are not distinguished from each other.

### 1.1.4 Planar Layout of Semiconductor Device

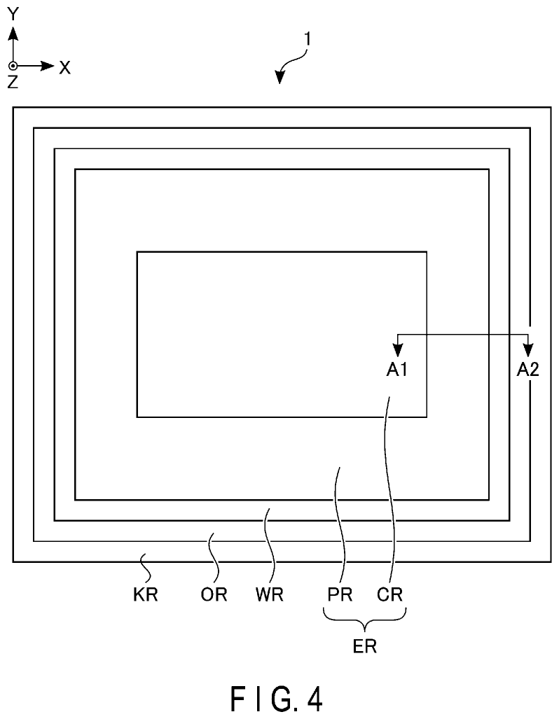

Next, an example of the planar layout of the semiconductor device 1 will be described with reference to FIG. 4. FIG. 4 is a plane view of the semiconductor device 1.

As shown in FIG. 4, a planar layout of the semiconductor device 1 roughly includes an element region ER, a wall region WR, an outer peripheral region OR, and a kerf region KR. Furthermore, the element region ER includes a core region CR and a peripheral circuit region PR.

The element region ER is a region in which elements that constitute the semiconductor device 1, such as the memory cell array 11, the sequencer 21, the voltage generator 22, the row decoder 23, and the sense amplifier 24, are provided.

The core region CR is, for example, a rectangular region provided in a central part of the element region ER. The memory cell array 11 is arranged in the core region CR of the array chip 10. The core region CR of the circuit chip 20 may include the row decoder 23, the sense amplifier 24, etc. The core region CR may be in any shape and arranged in any region. If the semiconductor device 1 has a plurality of memory cell arrays 11, the element region ER may have a plurality of core regions CR.

The peripheral circuit region PR is a square ring-shaped region, for example, that surrounds the outer periphery of the core region CR in the element region ER. In the peripheral circuit region PR, for example, the sequencer 21, the voltage generator 22, etc., are arranged. Alternatively, a plurality of external connection terminals used for coupling the semiconductor device 1 to an external device are arranged in the peripheral circuit region PR. The semiconductor device 1 transmits and receives signals to and from the external device via the external connection terminals. The semiconductor device 1 receives power supply externally via the external connection terminals.

The wall region WR is, for example, a square ring-shaped region provided so as to surround the outer periphery of the element region ER. The wall region WR is provided with a member for stabilizing the electric potential of a power supply line, a well, etc. by fixing the outer periphery of the semiconductor device 1 at the same electric potential (ground potential VSS). For example, the member provided on the wall region WR has a function of releasing static electricity to the substrate. This suppresses destruction of the elements caused by static electricity.

The outer peripheral region OR is, for example, a square ring-shaped region provided so as to surround the wall region WR. A plurality of semiconductor devices 1 are formed on a wafer and are cut off to be each separated for each chip in a dicing process. The outer peripheral region OR is provided to inhibit a crack or peeling of an interlayer insulating layer, etc. from reaching the inside of the semiconductor device 1 when such a crack or peeling occurs at an end portion of the semiconductor device 1 in the dicing process, for example.

The kerf region KR is, for example, a square ring-shaped region provided so as to surround the outer periphery of the outer peripheral region OR. The kerf region KR is an end region including a chip end portion. The kerf region KR is a region provided between the plurality of semiconductor devices 1 formed on the wafer. By cutting the kerf region KR in the dicing process, the plurality of semiconductor devices 1 formed on the wafer are cut to be separated into each chip. The kerf region KR is provided with, for example, alignment marks and patterns for characteristic checks used in manufacturing the semiconductor device 1. Structures in the kerf region KR may be removed through the dicing process.

### 1.1.5 Cross-Sectional Structure of Semiconductor Device

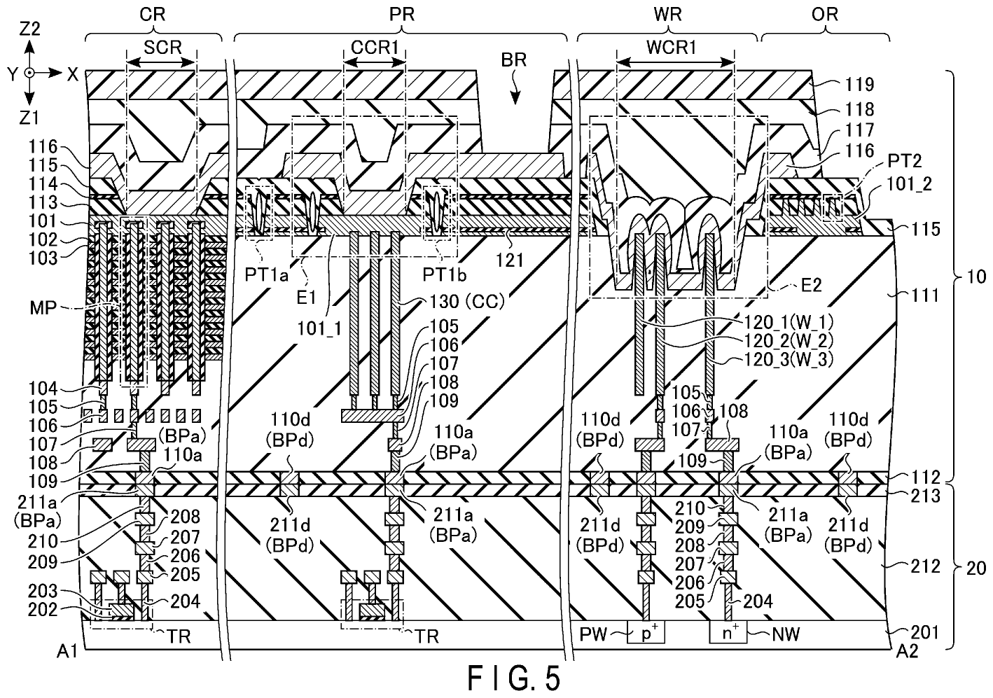

Next, an example of the cross-sectional structure of the semiconductor device 1 will be described with reference to FIG. 5. FIG. 5 is a cross-sectional view showing an example of the cross-sectional structure of the semiconductor device 1. The example in FIG. 5 shows a cross section in the X direction taken along the line A1 to A2 shown in FIG. 4.

As shown in FIG. 5, the semiconductor device 1 has the bonded structure in which the array chip 10 and the circuit chip 20 are bonded together. The array chip 10 includes a semiconductor layer 101, insulating layers 102, 111, 112, 113, 114, 115, 117, 118, and 121, interconnect layers 103, 106, 108, and 116, conductors 104, 105, 107, 109, 120, and 130, electrodes 110, a surface protective layer 119, and memory pillars MP. The electrodes 110 include electrodes 110a and 110d. The circuit chip 20 includes a semiconductor substrate 201, an N-type impurity diffusion region NW, a P-type impurity diffusion region PW, transistors TR, gate insulating films 202, gate electrodes 203, conductors 204, 206, 208, and 210, interconnect layers 205, 207, and 209, electrodes 211, and insulating layers 212 and 213. The electrode 211 includes electrodes 211a and 211d.

### 1.1.5.1 Cross-sectional Structure of Array Chip

Subsequently, a cross-sectional structure of the array chip 10 will be described with reference to FIG. 5.

### 1.1.5.1.1 Structure of Core Region

First, the core region CR of the array chip 10 will be described. The core region CR of the array chip 10 is provided with the memory cell array 11 and various interconnects for coupling the memory cell array 11 to the circuit chip 20.

The semiconductor layer 101 extends in the X direction and the Y direction. The semiconductor layer 101 provided in the core region CR functions as the source line SL. For example, the semiconductor layer 101 contains silicon. In the core region CR, the plurality of insulating layers 102 and the plurality of interconnect layers 103 are alternately stacked one by one on the semiconductor layer 101 facing in the Z1 direction. In the example shown in FIG. 5, ten insulating layers 102 and ten interconnect layers 103 are alternately stacked one by one. In other words, the plurality of interconnect layers 103 stacked apart in the Z direction are provided between the circuit chip 20 and the semiconductor layer 101. The interconnect layers 103 extend in the X direction. The interconnect layers 103 each function as one of the word line WL and the select gate lines SGD and SGS. The insulating layers 102 contain silicon oxide (SiO) as an insulating material. For example, the interconnect layers 103 contains tungsten (W) as a conductive material.

The plurality of memory pillars MP are provided in the core region CR. One memory pillar MP corresponds to one NAND string NS. For example, the memory pillar MP has a cylindrical shape extending in the Z direction. The memory pillar MP penetrates (passes through) the plurality of insulating layers 102 and the plurality of interconnect layers 103. An end portion (bottom surface) of each memory pillar MP in the Z2 direction reaches the film inside of the semiconductor layer 101. The memory pillar MP includes a semiconductor film extending in the Z direction. A part of the semiconductor film in the memory pillar MP is in contact with the semiconductor layer 101. Details of the configuration of the memory pillar MP will be described later.

The conductor 104 is provided on a surface facing in the Z1 direction of each memory pillar MP. For example, the conductor 104 has a cylindrical shape extending in the Z direction. The conductor 105 is provided on a surface facing in the Z1 direction of the conductor 104. For example, the conductor 105 provided in the core region CR has a cylindrical shape extending in the Z direction. Furthermore, the interconnect layer 106 is provided on a surface facing in the Z1 direction of the conductor 105. For example, in the core region CR, a plurality of interconnect layers 106 are provided side by side in the X direction and are each extending in the Y direction. Each of the memory pillars MP is electrically coupled to one of the plurality of interconnect layers 106 via the conductors 104 and 105. The interconnect layer 106 to which the memory pillar MP is coupled functions as a bit line BL. For example, the conductor 104 contains tungsten. For example, the conductor 105 and the interconnect layer 106 contain copper (Cu).

The conductor 107 is provided on a surface facing in the Z1 direction of the interconnect layer 106. For example, the conductor 107 provided in the core region CR has a cylindrical shape extending in the Z direction. The interconnect layer 108 is provided on a surface facing in the Z1 direction of the conductor 107. The conductor 109 is provided on a surface facing in the Z1 direction of the interconnect layer 108. For example, the conductor 109 provided in the core region CR has a cylindrical shape extending in the Z direction. In the core region CR, the electrode 110a is provided on a surface facing in the Z1 direction of the conductor 109. That is, each of the plurality of interconnect layers 106 in the core region CR is electrically coupled to one of the electrodes 110a via the conductor 107, the interconnect layer 108, and the conductor 109. The number of interconnect layers provided between the interconnect layer 106 and the electrode 110a is freely selected. Although not shown in FIG. 5, in the core region CR, the electrode 110a electrically coupling the interconnect layers 103 to the circuit chip 20 is provided in addition to the electrode 110a for coupling the interconnect layers 106 to the circuit chip 20. Each of the electrodes 110a is in contact with a corresponding one of the electrodes 211a of the circuit chip 20. Each pair of the electrodes 110a and 211a functions as a bonding pad BPa. The bonding pad BPa is an active pad.

For example, the conductor 107, the interconnect layer 108, the conductor 109, and the electrode 110a contain copper as a conductive material.

The insulating layer 111 is provided in such a manner as to cover the insulating layer 102, the interconnect layer 103, the memory pillars MP, the conductors 104, the conductors 105, the interconnect layer 106, the conductor 107, the interconnect layer 108, and the conductor 109. The insulating layer 112 is provided on a surface facing in the Z1 direction of the insulating layer 111. The plurality of electrodes 110 are provided in the identical layer to the insulating layer 112. The insulating layer 112 is in contact with the insulating layer 213 of the circuit chip 20. That is, a surface in which the insulating layer 112 is in contact with the insulating layer 213 corresponds to the bonding surface.

The insulating layers 113 and 114 are stacked on a surface facing in the Z2 direction of the semiconductor layer 101. Then, the insulating layer 115 is provided in such a manner as to cover the semiconductor layer 101 and the insulating layers 113 and 114. For example, the insulating layers 113 and 115 contain silicon oxide as an insulating material. For the insulating layer 114, an insulating material with a function of preventing oxidation of metal (e.g., copper) is used. For example, the insulating layer 114 contains silicon carbonitride (SiCN) or silicon nitride (SiN). The insulating layer 114 may be omitted.

The interconnect layer 116 is provided on a surface facing in the Z2 direction of the insulating layer 115. The semiconductor layer 101 in the core region CR is in contact with the interconnect layer 116 in a region from which the insulating layers 113 to 115 on the surface facing in the Z2 direction are removed. Hereinafter, a region in which the semiconductor layer 101 functioning as the source line SL is in contact with the interconnect layer 116 will also be referred to as an “SL connection region SCR”. That is, the SL connection region SCR is a region in which the insulating layer 115, the insulating layer 114, and the insulating layer 113 above the semiconductor layer 101 are removed from the core region CR. The interconnect layer 116 in the core region CR functions as a part of a path electrically coupling the semiconductor layer 101 (source line SL) to the circuit chip 20. For example, the interconnect layer 116 contains aluminum (Al).

The insulating layer 117 is provided on a surface facing in the Z2 direction of the interconnect layer 116. The insulating layer 118 is provided on a surface facing in the Z2 direction of the insulating layer 117. Then, the surface protective layer 119 is provided on a surface facing in the Z2 direction of the insulating layer 118. The insulating layers 117 and 118 and the surface protective layer 119 are provided in such a manner as to cover the element region ER, the wall region WR, and the inner peripheral portion of the outer peripheral region OR. That is, in the outer peripheral portion of the outer peripheral region OR and the kerf region KR, the insulating layers 117 and 118 and the surface protective layer 119 are removed. For example, the insulating layer 117 contains silicon oxide as an insulating material. For example, the insulating layer 118 contains silicon nitride as an insulating material with low permeability. For example, the surface protective layer 119 may contain a resin material such as polyimide.

### 1.1.5.1.2 Configuration of Peripheral Circuit Region

Next, the peripheral circuit region PR of the array chip 10 will be described.

The insulating layer 121 is provided inside the semiconductor layer 101 in the peripheral circuit region PR. The semiconductor layer 101 in the peripheral circuit region PR is separated by a protruding portion PT1a provided on the insulating layer 115, from the semiconductor layer 101 in the core region CR, that is, the semiconductor layer 101 functioning as the source line SL. In other words, the semiconductor layer 101 in the peripheral circuit region PR is electrically isolated from the semiconductor layer 101 functioning as the source line SL. For example, the protruding portion PT1a has a ring shape surrounding the memory cell array 11. The protruding portion PT1a may be provided inside the core region CR. The protruding portion PT1a extends in the Z1 direction from a surface facing in the Z1 direction of the insulating layer 115. The protruding portion PT1a penetrates (passes through) the insulating layers 114 and 113, the semiconductor layer 101, and the insulating layer 121 provided inside the semiconductor layer 101, and is in contact with the insulating layer 111. The protruding portion PT1a may internally include a void (gap).

The peripheral circuit region PR includes an external connection terminal region BR provided with an external connection terminal. In the external connection terminal region BR, the insulating layers 117 and 118 and the surface protective layer 119 are removed, and the interconnect layer 116 is partially exposed. The interconnect layer 116 functioning as an external connection terminal (provided with the external connection terminal) is electrically insulated from the interconnect layer 116 provided in the core region CR. The interconnect layer 116 provided with the external connection terminal is electrically coupled to the plurality of conductors 130 via the semiconductor layer 101. In the example shown in FIG. 5, three conductors 130 are arranged side by side in the X direction. Each of the conductors 130 functions as a contact plug CC. The contact plug CC is used for electrical coupling between interconnect layer 116 provided with the external connection terminal and the circuit chip 20. For example, the conductor 130 has a cylindrical shape extending in the Z direction. For example, the conductor 130 contains tungsten.

The semiconductor layer 101 in contact with the interconnect layer 116 is separated by a protruding portion PT1b provided on the insulating layer 115, from the surrounding semiconductor layer 101. For example, the protruding portion PT1b has a ring shape. The protruding portion PT1b extends in the Z1 direction from the surface facing in the Z1 direction of the insulating layer 115. The protruding portion PT1b penetrates (passes through) the insulating layers 114 and 113, the semiconductor layer 101, and the insulating layer 121 provided inside the semiconductor layer 101, and is in contact with the insulating layer 111. For example, the protruding portion PT1b may internally include a void (gap). Hereinafter, the semiconductor layer 101 separated by the protruding portion PT1b will be referred to as a “semiconductor layer 101_1” in a case where it is distinguished from the remaining portions of the semiconductor layer 101. Furthermore, a region in which the interconnect layer 116 is coupled to the semiconductor layer 101_1 will also be referred to as a “CC connection region CCR1”. The CC connection region CCR1 is a region from which the insulating layers 115, 114, and 113 on the semiconductor layer 101_1 are removed in the XY plane. The insulating layer 121 is not provided in at least a part of the semiconductor layer 101_1 when viewed in the Z direction. Furthermore, in the example shown in FIG. 5, the CC connection region CCR1 does not overlap with the external connection terminal region BR when viewed in the Z direction. That is, the interconnect layer 116 coupled to the semiconductor layer 101_1 inside the CC connection region CCR1 surrounded with the protruding portion PT1b extends along the XY plane on the insulating layer 115 including the protruding portion PT1b, and is exposed from the insulating layers 117 and 118 and the surface protective layer 119 in the external connection terminal region BR arranged outside the ring shape of the protruding portion PT1b, thereby serving as the external connection terminal.

The plurality of conductors 130 coupled to the single semiconductor layer 101_1 (the semiconductor layer 101_1 separated by the protruding portion PT1b from the surrounding semiconductor layer 101) are coupled to the single interconnect layer 106 via the conductors 105, for example. The interconnect layer 106 is electrically coupled to one of the electrodes 110a via the conductor 107, the interconnect layer 108, and the conductor 109. That is, in the peripheral circuit region PR, the electrode 110a for providing electrical coupling between the external device and the circuit chip 20 is provided. The interconnect layer 106 may be electrically coupled to the plurality of electrodes 110a via a plurality of sets of the conductor 107, the interconnect layer 108, and the conductor 109.

The plurality of electrodes 110a and 110d are provided in the identical layer to the insulating layer 112. Each of the electrodes 110a is in contact with a corresponding one of the electrodes 211a of the circuit chip 20. Each of the electrodes 110d is in contact with a corresponding one of the electrodes 211d of the circuit chip 20. Each pair of the electrodes 110d and 211d functions as a bonding pad BPd. The bonding pad BPd is a dummy pad. The bonding pad BPd is electrically isolated from the memory cell array 11 and various interconnects in the array chip 10, and the semiconductor substrate 201 and various interconnects in the circuit chip 20.

### 1.1.5.1.3 Configuration of Wall Region

Next, the wall region WR of the array chip 10 will be described. The wall region WR of the array chip 10 is provided with a plurality of wall structures W, and various interconnects for coupling the wall structures W to the circuit chip 20. In the example shown in FIG. 5, the wall structures include three wall structures W_1, W_2, and W_3. The wall structures W_1 to W_3 respectively include conductors 120_1 to 120_3. For example, the conductors 120_1 to 120_3 contain tungsten.

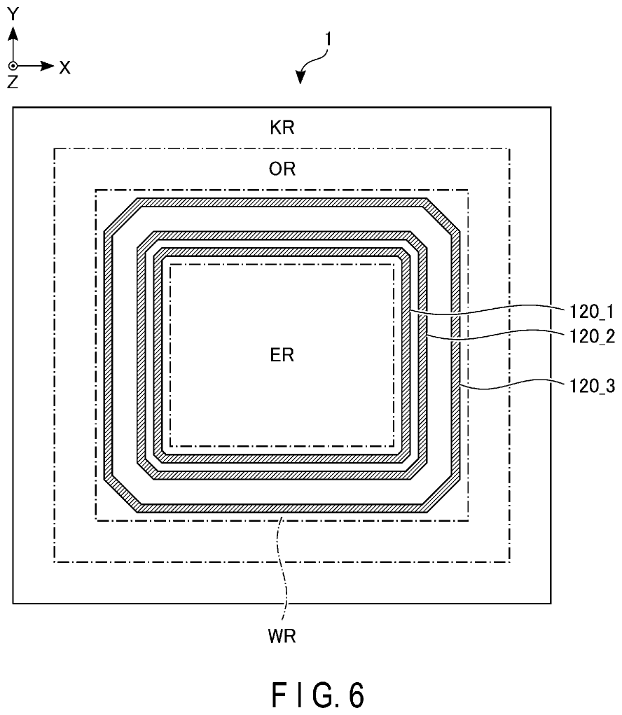

The planar layout of the conductors 120_1 to 120_3 will be described with reference to FIG. 6. FIG. 6 is a plane view showing an example of the planar layout of the conductors 120_1 to 120_3. FIG. 6 omits portions other than the conductors 120_1 to 120_3 in order to simplify the description.

As shown in FIG. 6, for example, the conductors 120_1 to 120_3 each have a substantially square ring shape in the XY plane. The conductors 120_1 to 120_3 are not in contact with each other. The conductors 120_1 to 120_3 are not necessarily formed in a square ring shape as long as they are in a ring shape. Furthermore, each of the conductors 120_1 to 120_3 may be divided into a plurality of pieces in the XY plane. The conductor 120_1 is provided in such a manner as to surround the element region ER (peripheral circuit region PR). The conductor 120_2 is provided in such a manner as to surround the conductor 120_1. The conductor 120_3 is provided in such a manner as to surround the conductor 120_2.

As shown in FIG. 5, each of the conductors 120_1 to 120_3 extends in the Z direction. The end portions in the Z2 direction of the conductors 120_1 to 120_3 are coupled to the interconnect layer 116. More specifically, in the vicinity of the end portions in the Z2 direction of the conductors 120_1 to 120_3, the semiconductor layer 101 and the insulating layers 113 to 115 are removed, and a surface facing in the Z2 direction of the insulating layer 111 is dug in the Z1 direction. That is, a trench of the insulating layer 111 is formed. By this, the end portions in the Z2 direction of the conductors 120_1 to 120_3 protrude from the dug surface of the insulating layer 111 (the bottom surface of the trench). The interconnect layer 116 covers the end portions of the conductors 120_1 to 120_3 protruding in the Z2 direction. Hereinafter, a trench region of the insulating layer 111, in which the interconnect layer 116 is coupled to the conductors 120_1 to 120_3 will also be referred to as a “wall connection region WCR1”. The insulating layer 115 is provided on the side surface of the semiconductor layer 101. Therefore, the interconnect layer 116 is not in contact with the semiconductor layer 101. The insulating layer 117 is provided in such a manner as to cover the interconnect layer 116. A void may be provided inside the insulating layer 117. The interconnect layer 116 provided in the wall region WR is electrically isolated from the interconnect layer 116 provided in the core region CR and the interconnect layer 116 provided in the peripheral circuit region PR.

The end portion in the Z1 direction of the conductor 120_1 is not coupled to the conductor 105. The end portion in the Z1 direction of the conductor 120_2 is electrically coupled to the electrode 110a via the conductor 105, the interconnect layer 106, the conductor 107, the interconnect layer 108, and the conductor 109. Similarly, the end portion in the Z1 direction of the conductor 120_3 is electrically coupled to the electrode 110a via the conductor 105, the interconnect layer 106, the conductor 107, the interconnect layer 108, and the conductor 109.

Each of the conductor 105, the interconnect layer 106, the conductor 107, the interconnect layer 108, the conductor 109, and the electrode 110a electrically coupled to the conductor 120_2 may have a square ring shape surrounding the element region ER. Each of the conductor 105, the interconnect layer 106, the conductor 107, the interconnect layer 108, the conductor 109, and the electrode 110a electrically coupled to the conductor 120_3 may have a square ring shape surrounding the conductor 105, the interconnect layer 106, the conductor 107, the interconnect layer 108, the conductor 109, and the electrode 110a electrically coupled to the conductor 120_2.

As with the peripheral circuit region PR, the plurality of electrodes 110a and 110d are provided in the identical layer to the insulating layer 112.

### 1.1.5.1.4 Configuration of Outer Peripheral Region

Next, the outer peripheral region OR of the array chip 10 will be described. The semiconductor layer 101 provided in the outer peripheral region OR is electrically insulated from the semiconductor layer 101 provided in the core region CR and the semiconductor layer 101 provided in the peripheral circuit region PR. Hereinafter, the semiconductor layer 101 provided in the outer peripheral region OR will be referred to as a “semiconductor layer 101_2” in a case where it is specified. At least a part of the semiconductor layer 101_2 is covered with (protected by) the surface protective layer 119. That is, at least a part of the semiconductor layer 101_2 is not provided in the Z direction between the circuit chip 20 and the surface protective layer 119. In other words, a surface of a part of the outer peripheral region OR is not protected by the surface protective layer 119.

A plurality of protruding portions PT2 extending in the Z2 direction are provided on a surface facing in the Z2 direction of the semiconductor layer 101_2. For example, the protruding portions PT2 penetrate the insulating layer 113. A surface facing in the Z2 direction of each protruding portion PT2 is in contact with the insulating layer 114. At least a part of the semiconductor layer 101_2 is not provided with the insulating layer 121 when viewed in the Z direction. The protruding portions PT2 ground the semiconductor layer 101 on a substrate (not shown) of the array chip 10 during the manufacturing process of the array chip 10. For example, the protruding portions PT2 are used to suppress an occurrence of arcing due to charging-up of the semiconductor layer 101 during dry etching. The protruding portions PT2 may not be provided.

In the outer peripheral region OR of the array chip 10, the plurality of electrodes 110d are provided in the identical layer to the insulating layer 112.

### 1.1.5.2 Cross-Sectional Structure of Circuit Chip

Next, the cross-sectional structure of the circuit chip 20 will be described.

In the element region ER (the core region CR and the peripheral circuit region PR), a plurality of transistors TR are provided on a surface facing in the Z2 direction of the semiconductor substrate 201. The transistors TR are used as elements inside the sequencer 21, the voltage generator 22, the row decoder 23, and the sense amplifier 24. The transistors TR include the gate insulating film 202, the gate electrode 203, and a source and a drain (not shown) formed in the semiconductor substrate 201. The gate insulating film 202 is provided on the surface facing in the Z2 direction of the semiconductor substrate 201. The gate electrode 203 is provided on a surface facing in the Z2 direction of the gate insulating film 202.

The transistors TR are not provided in the wall region WR and the outer peripheral region OR.

In the element region ER, the conductors 204 are provided on the surfaces facing in the Z2 direction of the gate electrode 203 and the semiconductor substrate 201. In the wall region WR, the conductors 204 are provided on the surfaces facing in the Z2 direction of the N-type impurity diffusion region NW provided in the semiconductor substrate 201 and the P-type impurity diffusion region PW provided in the semiconductor substrate 201.

The interconnect layer 205 is provided on a surface facing in the Z2 direction of the conductor 204. The conductor 206 is provided on a surface facing in the Z2 direction of the interconnect layer 205. The interconnect layer 207 is provided on a surface facing in the Z2 direction of the conductor 206. The conductor 208 is provided on a surface facing in the Z2 direction of the interconnect layer 207. The interconnect layer 209 is provided on a surface facing in the Z2 direction of the conductor 208. The conductor 210 is provided on a surface facing in the Z2 direction of the interconnect layer 209. For example, each of the conductors 204, 206, 208, and 210 provided in the element region ER has a cylindrical shape extending in the Z direction. Each of the conductors 204, 206, 208, and 210 and the interconnect layers 205, 207, and 209 provided in the wall region WR has a square ring shape surrounding the element region ER. The N-type impurity diffusion region NW and the P-type impurity diffusion region PW provided in the wall region WR may each have a square ring shape as with these conductors and interconnect layers, or may be provided in such a manner as to have a plurality of regions arranged apart from each other along the square ring shape so as to surround the element region ER. The number of interconnect layers provided in the circuit chip 20 is freely selected.

The insulating layer 212 is provided on a surface facing in the Z2 direction of the semiconductor substrate 201. The insulating layer 212 is provided in such a manner as to cover the transistor TR, the conductor 204, the interconnect layer 205, the conductor 206, the interconnect layer 207, the conductor 208, the interconnect layer 209, and the conductor 210. The insulating layer 213 is provided on the upper surface in the Z2 direction of the insulating layer 212.

The electrodes 211a and 211d are provided in the identical layer to the insulating layer 213. The electrode 211a is coupled to the electrode 110a and the conductor 210. The electrode 211d is coupled to the electrode 110d. In the wall region WR, the electrode 211a electrically coupled to the conductor 120_2 may have a square ring shape surrounding the element region ER. The electrode 211a electrically coupled to the conductor 120_3 may have a square ring shape surrounding the electrode 211a electrically coupled to the conductor 120_2.

The gate electrode 203, the conductors 204, 206, 208, and 210, the interconnect layers 205, 207, and 209, and the electrodes 211a and 211d are made of a conductive material and may contain, e.g., a metallic material, a p-type semiconductor, or an n-type semiconductor. For example, the electrodes 211a and 211d contain copper. For example, the gate insulating film 202, the insulating layer 212, and the insulating layer 213 contain silicon oxide as an insulating material.

In the example shown in FIG. 5, the conductor 120_2 of the array chip 10 is electrically coupled to the P-type impurity diffusion region PW of the semiconductor substrate 201 of the circuit chip 20. The conductor 120_3 of the array chip 10 is electrically coupled to the N-type impurity diffusion region NW of the semiconductor substrate 201 of the circuit chip 20. The conductor 120_3 may be electrically coupled to the P-type impurity diffusion region PW, and the conductor 120_2 may be electrically coupled to the N-type impurity diffusion region NW. Furthermore, for example, the conductor 120_1 may be electrically coupled to the P-type impurity diffusion region PW.

### 1.1.6 Cross-Sectional Structure of Bonding Pad

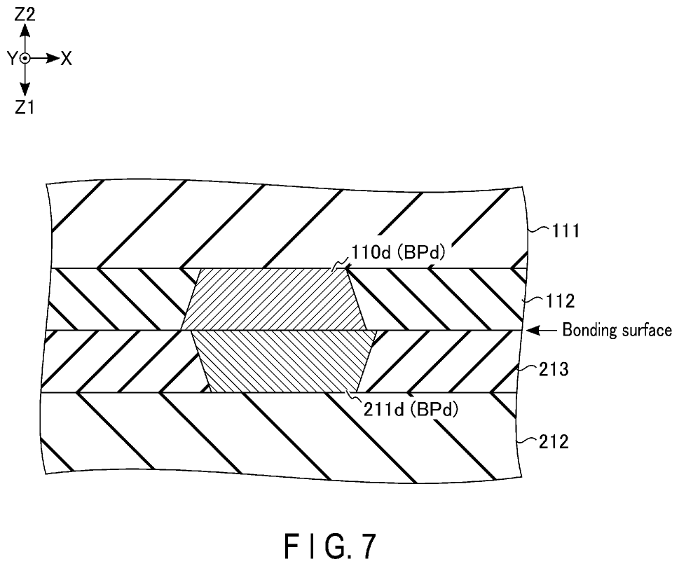

Next, a cross-sectional structure of the bonding pad BP will be described with reference to FIG. 7. FIG. 7 is a cross-sectional view showing an example of the cross-sectional structure of the bonding pad BPd. The following description regarding the bonding pad BPd applies to the bonding pad BPa.

As shown in FIG. 7, the electrode 110d is coupled to the electrode 211d during a bonding process for bonding the array chip 10 to the circuit chip 20. In the example shown in FIG. 7, the electrodes 110d and 211d in a bonding surface are substantially equal in area. In such a case, use of copper for the electrodes 110d and 211d may cause integration of copper in the electrode 110d and copper in the electrode 211d, thereby making it difficult to recognize a boundary in copper therebetween. However, bonding can be recognized according to distortion in the shape of the electrodes 110d and 211d bonded together, which is caused by displacement in bonding, and the displacement of barrier metals of copper (occurrence of discontiguous portions in the side surfaces).

Furthermore, in the case of forming the electrodes 110d and 211d by a damascene method, the side surface of each electrode has a tapered shape. For this reason, the cross-sectional shape in the Z direction of a portion in which the electrode 110d is bonded to the electrode 211d shows that the side wall is shaped into a non-rectangular form, not a straight form.

Furthermore, in the case of bonding the electrode 110d to the electrode 211d, the bottom surface, the side surface, and the upper surface of copper forming these electrodes are covered with a barrier metal. On the other hand, in a general interconnect layer using copper, an insulation layer (SiN, SiCN, etc.) having a function of preventing oxidation of copper is formed on the upper surface of the copper, and no barrier metal is provided. In this manner, even if displacement in bonding has not occurred, the above configuration can be distinguished from a general interconnect layer.

### 1.1.7 Cross-Sectional Structure of Memory Cell Array

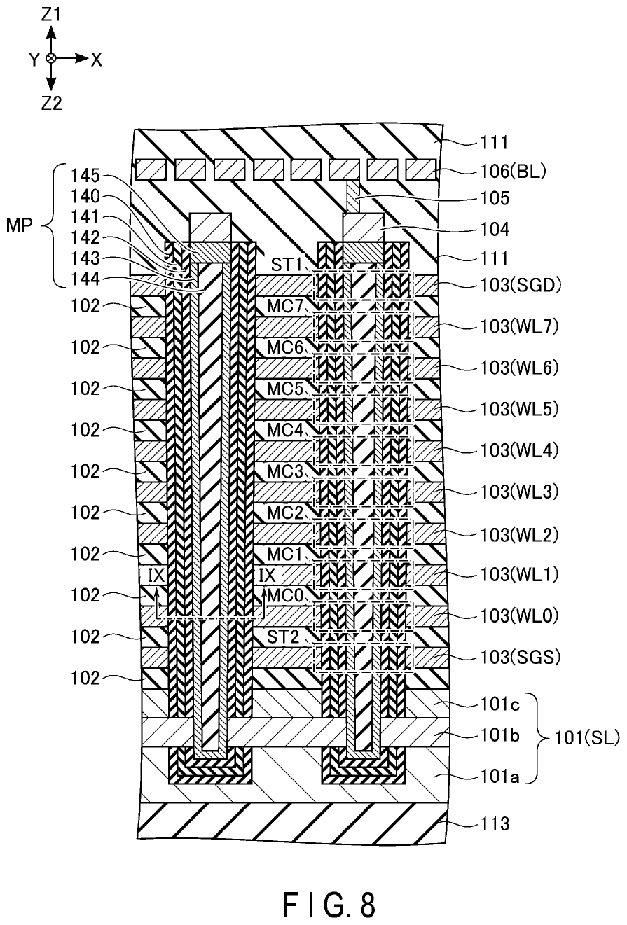

Next, a cross-sectional structure of the memory cell array 11 will be described with reference to FIG. 8. FIG. 8 is a cross-sectional view showing an example of the memory cell array 11. FIG. 8 shows two memory pillars MP included in the memory cell array 11.

As shown in FIG. 8, the semiconductor layer 101 contains, for example, three semiconductor layers 101a, 101b, and 101c. The semiconductor layer 101b is provided on the surface facing in the Z1 direction of the semiconductor layer 101a. The semiconductor layer 101c is provided on the surface facing in the Z1 direction of the semiconductor layer 101b. The semiconductor layer 101b is formed by, for example, replacing the insulating layer 121 provided between the semiconductor layer 101a and the semiconductor layer 101c. The semiconductor layers 101a to 101c include, for example, silicon. Furthermore, the semiconductor layers 101a to 101c contain phosphorus (P) as a semiconductor impurity.

On the surface facing in the Z1 direction of the semiconductor layer 101, ten insulating layers 102 and ten interconnect layers 103 are alternately stacked one by one. In the example shown in FIG. 8, ten interconnect layers 103 function as a select gate line SGS, word lines WL0 to WL7, and a select gate line SGD in order from the interconnect layer 103 closest to the semiconductor layer 101. A plurality of interconnect layers 103 that function as the select gate lines SGS and a plurality of interconnect layers 103 that function as the select gate line SGD may be provided. For example, a stacked structure of titanium nitride (TiN)/tungsten (W) may be used as a conductive material of the interconnect layers 103. In this case, titanium nitride is formed so as to cover the tungsten. Titanium nitride has a function as a barrier layer for suppressing oxidation of tungsten or as an adhesion layer for enhancing adhesion of tungsten in a case where tungsten is formed by, for example, chemical vapor deposition (CVD). The interconnect layers 103 may contain a high dielectric constant material such as aluminum oxide (AlO). In this case, the high dielectric constant material is formed so as to cover the conductive material. For example, in each of the interconnect layers 103, the high dielectric constant material is provided in such a manner as to be in contact with the insulating layers 102 provided above and below each interconnect layer 103 and the side surface of the memory pillar MP. Titanium nitride is provided in such a manner as to be in contact with the high dielectric constant material. Tungsten is then provided in such a manner as to be in contact with titanium nitride and fill the inside of each interconnect layer 103. For example, in the case of aluminum oxide being provided as the high dielectric constant material, the memory cell transistor MC will also be referred to as a metal-oxide-nitride-oxide-silicon (MONOS) type.

The insulating layer 111 is provided on the surface facing in the Z1 direction of the interconnect layer 103 that functions as the select gate line SGD.

The plurality of memory pillars MP are provided in the memory cell array 11. For example, the memory pillars MP each have an approximately cylindrical shape extending in the Z direction. The memory pillars MP each penetrate ten interconnect layers 103. The bottom surface of each memory pillar MP reaches the semiconductor layer 101. The memory pillars MP may be each configured so that a plurality of pillars are connected in the Z direction.

An internal configuration of the memory pillar MP will be described. The memory pillar MP includes a block insulating film 140, a charge storage film 141, a tunnel insulating film 142, a semiconductor film 143, a core film 144, and a cap film 145.

The block insulating film 140, the charge storage film 141, and the tunnel insulating film 142 are stacked in this order from the outer side on a part of the side surface and the bottom surface facing in the Z2 direction of the memory pillar MP. More Specifically, in the identical layer to the semiconductor layer 101b and the vicinity thereof, the block insulating film 140, the charge storage film 141, and the tunnel insulating film 142 on the side surface of the memory pillar MP are removed. The semiconductor film 143 is provided in such a manner as to be in contact with the side surface and the bottom surface of the tunnel insulating film 142, and the semiconductor layer 101b. The semiconductor film 143 is a region in which channels of the memory cell transistors MC and the select transistors ST1 and ST2 are to be formed. The inside of the semiconductor film 143 is filled with the core film 144. The cap film 145 is provided on upper ends of the semiconductor film 143 and the core film 144 in an upper portion of the memory pillar MP in the Z1 direction. The side surface of the cap film 145 is in contact with the tunnel insulating film 142. For example, the cap film 145 contains silicon. The conductor 104 is provided on a surface facing in the Z1 direction of the cap film 145. The conductor 105 is provided on a surface facing in the Z1 direction of the conductor 104. The conductor 105 is electrically coupled to the interconnect layer 106.

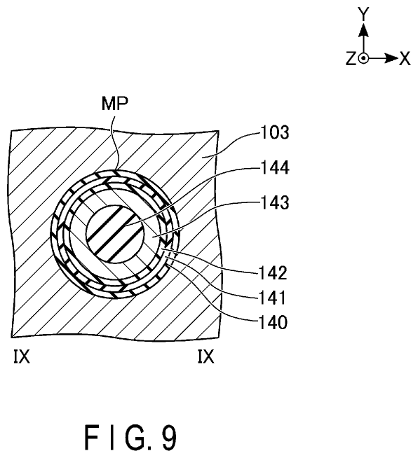

An example of the cross-sectional structure along the XY plane of the memory pillar MP will be described with reference to FIG. 9. FIG. 9 is a cross-sectional view taken along the line IX-IX of FIG. 8. More specifically, FIG. 9 shows a cross-sectional structure of the memory pillar MP in a layer including the interconnect layer 103.

In the cross-section including the interconnect layer 103, the core film 144 is provided in, for example, the central portion of the memory pillar MP. The semiconductor film 143 surrounds the side surface of the core film 144. The tunnel insulating film 142 surrounds the side surface of the semiconductor film 143. The charge storage film 141 surrounds the side surface of the tunnel insulating film 142. The block insulating film 140 surrounds the side surface of the charge storage film 141. The interconnect layer 103 surrounds the side surface of the block insulating film 140.

The semiconductor film 143 serves as a channel (current path) for the memory cell transistors MC0 to MC7 and the select transistors ST1 and ST2. For example, the tunnel insulating film 142 and the block insulating film 140 each contain silicon oxide. The charge storage film 141 has a function of storing charges. For example, the charge storage film 141 contains silicon nitride.

As shown in FIG. 8, the memory pillars MP in combination with the interconnect layers 103 respectively functioning as the word lines WL0 to WL7 respectively form the memory cell transistors MC0 to MC7. Similarly, the memory pillars MP in combination with the interconnect layer 103 functioning as the select gate line SGD form the select transistors ST1. Similarly, the memory pillars MP in combination with the interconnect layer 103 functioning as the select gate line SGS form the select transistors ST2. In this manner, the memory pillars MP are each capable of functioning as one NAND string NS.

### 1.1.8 Configuration of CC Connection Region

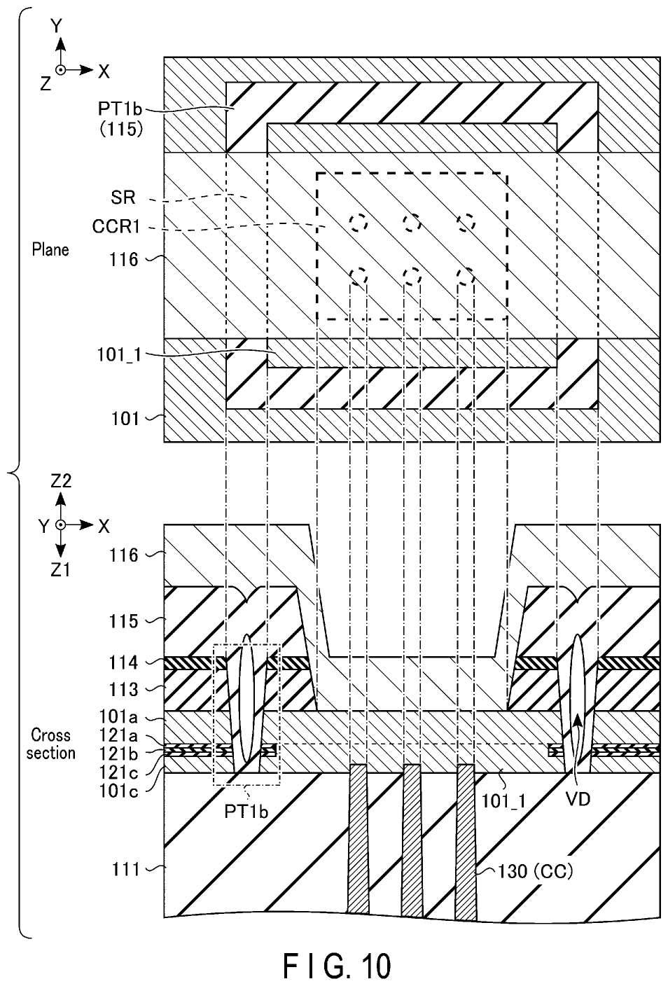

Next, an example of the configuration of the CC connection region CCR1 will be described with reference to FIG. 10. FIG. 10 shows a plane view and a cross-sectional view of a region E1 shown in FIG. 5. The plane view of FIG. 10 omits layers other than the semiconductor layers 101 and 101_1, the protruding portion PT1b of the insulating layer 115, and the interconnect layer 116. In addition, the cross-sectional view of FIG. 10 omits the insulating layers 117 and 118 and the surface protective layer 119 on the surface facing in the Z2 direction of the interconnect layer 116.

As shown in the plane view in FIG. 10, for example, the protruding portion PT1b of the insulating layer 115 has a square ring shape. A region provided with the protruding portion PT1b will also be referred to as a “separation region SR”. The separation region SR separates the semiconductor layer 101_1 from the remaining portions of the semiconductor layer 101. That is, the protruding portion PT1b functions as the separation insulating layer that separates the semiconductor layer 101_1. In the CC connection region CCR1, the surface facing in the Z2 direction of the semiconductor layer 101_1 is in contact with the interconnect layer 116. In the example shown in FIG. 10, six conductors 130 are in contact with one semiconductor layer 101_1. In other words, six conductors 130 (contact plugs CC) are electrically coupled to one interconnect layer 116 via the semiconductor layer 101_1.

As shown in the cross-sectional view in FIG. 10, the semiconductor layer 101 in the peripheral circuit region PR includes two semiconductor layers (a pair of semiconductor layers) 101a and 101c, and does not include the semiconductor layer 101b. That is, an intermediate semiconductor layer is not provided between the semiconductor layer 101c in a lower side and the semiconductor layer 101a in an upper side. The insulating layer 121 is provided between the semiconductor layer 101a and the semiconductor layer 101c. For example, the insulating layer 121 includes three insulating layers 121a, 121b, and 121c. In the portions other than the core region CR (the memory cell array 11), a replacement process for replacing the insulating layer 121 (insulating layers 121a to 121c) with the semiconductor layer 101b is not performed. Therefore, the insulating layers 121a to 121c remain inside the semiconductor layer 101. For example, the insulating layers 121a and 121c contain silicon oxide as an insulating material. For example, the insulating layer 121b contains silicon nitride as an insulating material. For the insulating layer 121b, a material that can provide a sufficient etching selection ratio with respect to the insulating layers 121a and 121c is used. That is, a material different in film composition from that of the insulating layers 121a and 121c is selected for the insulating layer 121b.

The semiconductor layer 101_1 contains a region in which the insulating layer 121 is not provided between the semiconductor layer 101a and the semiconductor layer 101c. In the example shown in FIG. 10, the insulating layer 121 is removed from the CC connection region CCR1 and its neighboring region. Thus, the semiconductor layer 101a and the semiconductor layer 101c of the semiconductor layer 101_1 are in contact with each other. Therefore, the conductor 130 is electrically coupled to the interconnect layer 116 via the semiconductor layer 101_1 (semiconductor layers 101a and 101c). A region in which the semiconductor layer 101a is in contact with the semiconductor layer 101c, that is, a region in which the insulating layer 121 is not provided may be wider than the separation region SR. In this case, the semiconductor layer 101_1 does not include the insulating layer 121.

The interconnect layer 116 is formed on the semiconductor layer 101_1, which is relatively flat, in the CC connection region CCR1. Furthermore, a step between the interconnect layer 116 on the surface facing in the Z2 direction of the insulating layer 115 and the interconnect layer 116 in the CC connection region CCR1 is small as compared to a case of the wall connection region WCR1 to be described later. Therefore, a reduction in film thickness of the interconnect layer 116 due to deteriorations in step coverage of the interconnect layer 116 is smaller than that of the wall connection region WCR1.

The protruding portion PT1b of the insulating layer 115 penetrates the insulating layer 114, the insulating layer 113, the semiconductor layer 101a, the insulating layer 121 (insulating layers 121a to 121c), and the semiconductor layer 101c. In a case where the region not provided with the insulating layer 121 is wider than the separation region SR, the protruding portion PT1b may not penetrate the insulating layer 121.

Voids VD are provided inside the protruding portion PT1b. The voids VD depend on the step coverage at the time of formation of the insulating layer 115. In the example shown in FIG. 10, the insulating layer 115 is formed by a plasma CVD method. For example, the step coverage of the insulating layer 115 formed by the plasma CVD method is not as good as the insulating layer 115 formed by atomic layer deposition (ALD). This facilitates formation of the voids VD. The voids VD are not necessarily formed.

### 1.1.9 Configuration of Wall Connection Region

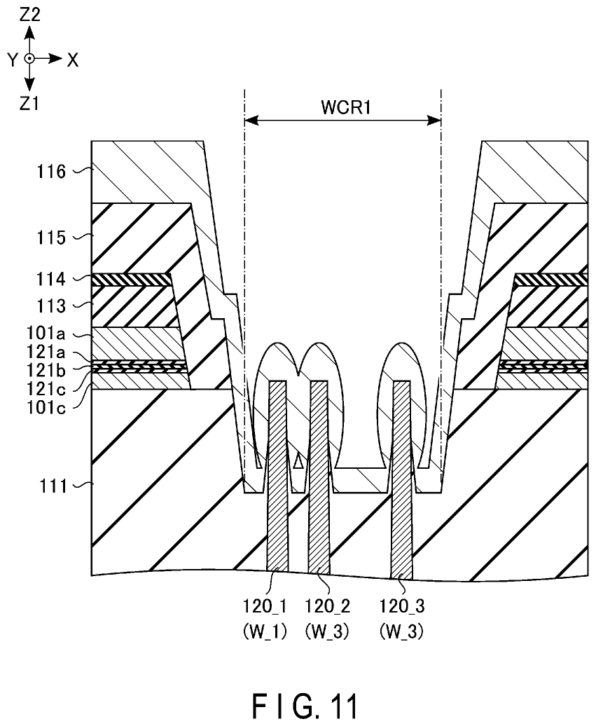

Next, a structure of the wall connection region WCR1 will be described with reference to FIG. 11. FIG. 11 is a cross-sectional view of the region E2 shown in FIG. 5. The example shown in FIG. 11 omits the insulating layers 117 and 118 and the surface protective layer 119 on the surface facing in the Z2 direction of the interconnect layer 116.

As shown in FIG. 11, the semiconductor layer 101 in the wall region WR includes two semiconductor layers 101a and 101c and does not include the semiconductor layer 101b. The insulating layer 121 (insulating layers 121a to 121c) is provided between the semiconductor layer 101a and the semiconductor layer 101c. In the wall connection region WCR1 and its neighboring region, the semiconductor layer 101, the insulating layer 121, the insulating layer 113, and the insulating layer 114 are removed. The insulating layer 115 is formed in such a manner as to cover the surface facing in the Z2 direction of the insulating layer 114 and the side surfaces of the semiconductor layer 101, the insulating layer 121, the insulating layer 113, and the insulating layer 114. The insulating layer 115 provided on the side surface of the semiconductor layer 101, the insulating layer 121, the insulating layer 113, and the insulating layer 114 function as a side wall for electrically insulating the semiconductor layer 101 from the interconnect layer 116.

In the wall connection region WCR1, the insulating layer 115 is removed. The surface facing in the Z2 direction of the insulating layer 111 is dug in the Z1 direction. By this, the end portions in the Z2 direction of the conductors 120_1 to 120_3 protrude from the dug surface of the insulating layer 111 (the bottom surface of the trench). Hereinafter, the portions of the conductors 120_1 to 120_3, which protrude in the Z2 direction from the bottom surface of the trench of the insulating layer 111, will be referred to as protruding portions of the conductors 120_1 to 120_3. On the side surfaces of the protruding portions of the conductors 120_1 to 120_3, the insulating layer 111 may partially remain.

The interconnect layer 116 is formed in such a manner as to cover the protruding portions of the conductors 120_1 to 120_3. That is, the interconnect layer 116 is in contact with the conductors 120_1 to 120_3. A shape of the interconnect layer 116 covering the conductors 120_1 to 120_3 depends on the step coverage of the interconnect layer 116. In the example shown in FIG. 11, the interconnect layer 116 is formed using sputtering. The step coverage of the interconnect layer 116 formed by the sputtering is not as good as the interconnect layer 116 formed by the ALD. Therefore, the thickness of the interconnect layer 116 in a root portion of the protruding portion of the conductor 120 (in the neighboring region of a bottom of trench of the insulating layer 111) is thinner than that of the remaining regions. This tendency becomes more apparent as the amount of protrusion in the protruding portion of the conductor 120 increases.

### 1.2 Manufacturing Method of Array Chip

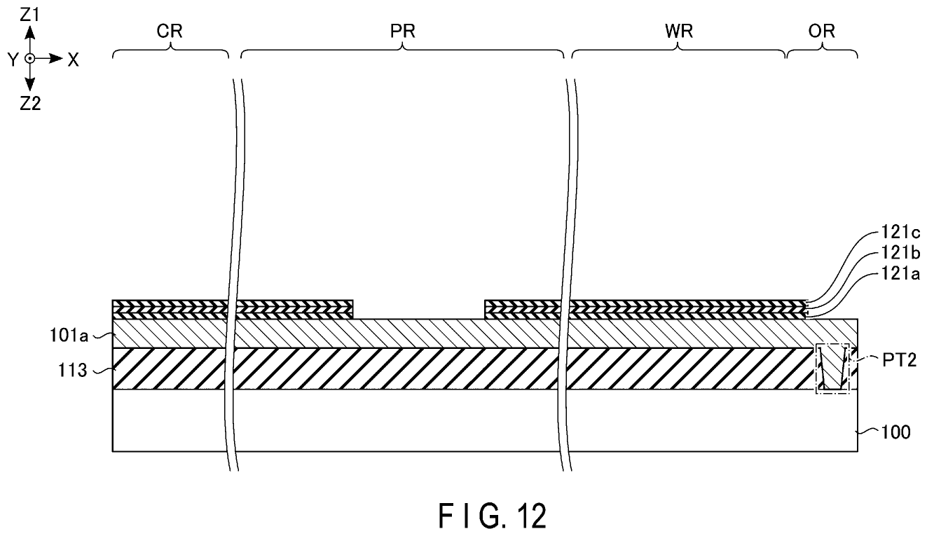

Next, an example of the manufacturing method of the array chip 10 will be described with reference to FIG. 12 to FIG. 17. FIG. 12 to FIG. 17 are each a cross-sectional view showing an example of a manufacturing process of the array chip 10. The following description focuses on the process until formation of the conductor 130.

As shown in FIG. 12, the insulating layer 113 is formed on the semiconductor substrate 100 of the array chip 10. A region (trench) corresponding to the protruding portion PT2 is formed by processing the insulating layer 113. Thereafter, the semiconductor layer 101a is formed. At this time, a region (trench) corresponding to a protruding portion PT2 is also filled in to thereby form the protruding portion PT2. This protruding portion PT2 is in contact with the semiconductor substrate 100. The insulating layers 121a, 121b, and 121c are formed sequentially on the semiconductor layer 101a. Thereafter, the insulating layers 121a, 121b, and 121c located in the region corresponding to the semiconductor layer 101_1 (that is, the CC connection region CCR1) and the region corresponding to the semiconductor layer 101_2 (that is, the neighboring region of the protruding portion PT2) are removed.

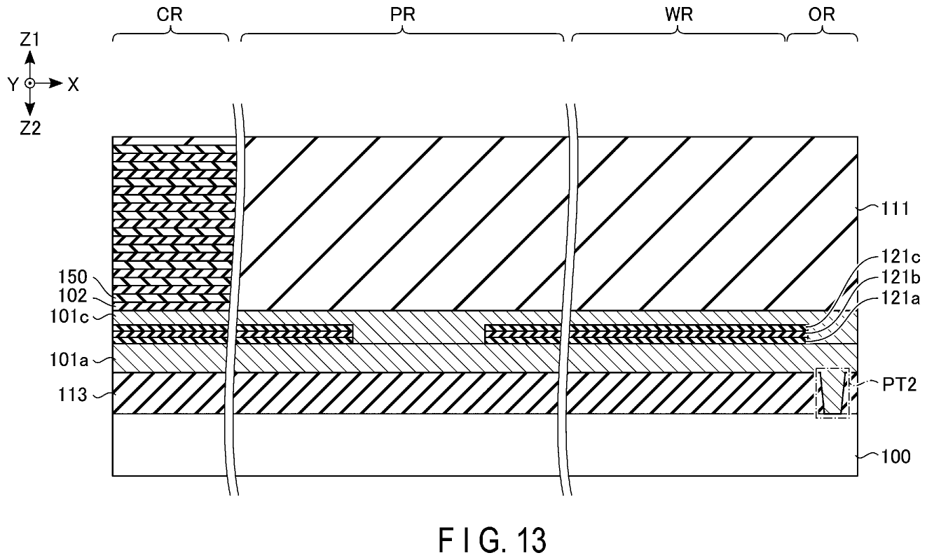

As shown in FIG. 13, the semiconductor layer 101c is formed in such a manner as to cover the semiconductor layer 101a and the insulating layers 121a, 121b, and 121c. In the region from which the insulating layers 121a, 121b, and 121c are removed, the semiconductor layers 101a and 101c are in contact with each other. Subsequently, in the memory cell array 11 in the core region CR, the plurality of insulating layers 102 and a plurality of sacrifice layers 150 are alternately stacked one by one. The sacrifice layers 150 are replaced with the interconnect layers 103 through a process to be described later. For the sacrifice layer 150, for example, silicon nitride is used. Thereafter, the insulating layer 111 is formed in such a manner as to cover the entire surface facing in the Z1 direction of the semiconductor substrate 100.

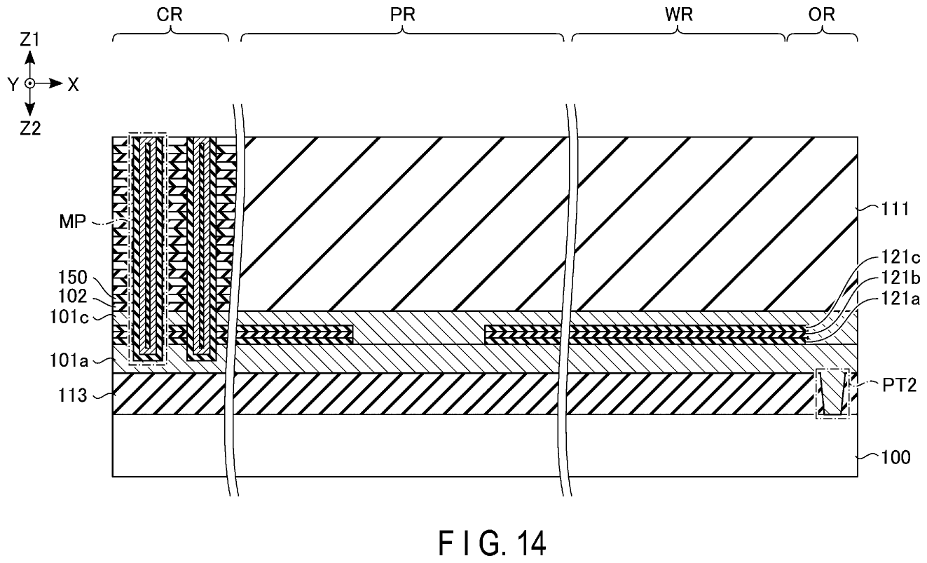

As shown in FIG. 14, the memory pillars MP are formed in the memory cell array 11 in the core region CR. More specifically, memory holes respectively corresponding to the memory pillars MP are formed. Each of the memory holes penetrates the sacrifice layers 150, the insulating layers 102, the semiconductor layer 101c, and the insulating layers 121a to 121c. A bottom surface of the memory hole reaches a film inside of the semiconductor layer 101a. The memory holes are filled in by sequentially forming the block insulating film 140, the charge storage film 141, the tunnel insulating film 142, the semiconductor film 143, and the core film 144. Next, the semiconductor film 143 and the core film 144 in the upper portion of the memory pillar MP are removed to thereby form the cap film 145. The block insulating film 140, the charge storage film 141, the tunnel insulating film 142, the semiconductor film 143, the core film 144, and the cap film 145 on the surface facing in the Z1 direction of the insulating layer 111 are removed.

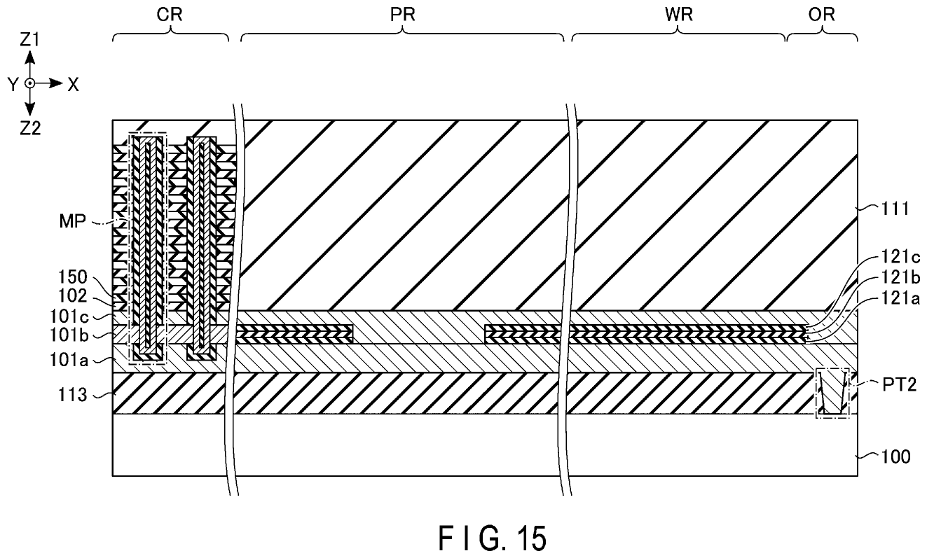

As shown in FIG. 15, the insulating layer 111 is formed in such a manner as to cover an upper surface of the memory pillar MP. Next, the insulating layer 121 is replaced with the semiconductor layer 101b. More specifically, for example, slits (not shown) are formed in the memory cell array 11. Each slit penetrates the insulating layer 111, the sacrifice layer 150, the insulating layer 102, the semiconductor layer 101c, and the insulating layer 121c. A bottom surface of the slit reaches the film inside of the insulating layer 121. For example, the insulating layer 121, and a part of the block insulating film 140, a part of the charge storage film 141, and a part of the tunnel insulating film 142 in each of the memory pillars MP are removed from the side surfaces of slits. The semiconductor layer 101b is formed in the region from which the insulating layer 121, the block insulating films 140, the charge storage films 141, and the tunnel insulating films 142 have been removed. The semiconductor layer 101 is coupled to the semiconductor film 143 of each memory pillar MP.

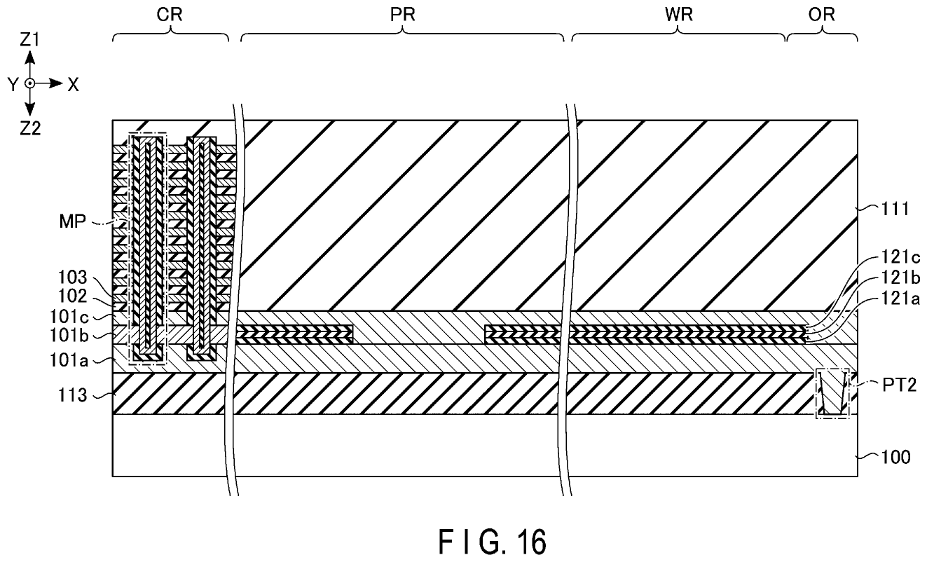

As shown in FIG. 16, next, the sacrifice layers 150 are replaced with the interconnect layers 103. More specifically, the sacrifice layers 150 are removed from the side surfaces of the slits by, for example, wet etching. The interconnect layers 103 are formed in the regions from which the sacrifice layers 150 have been removed.

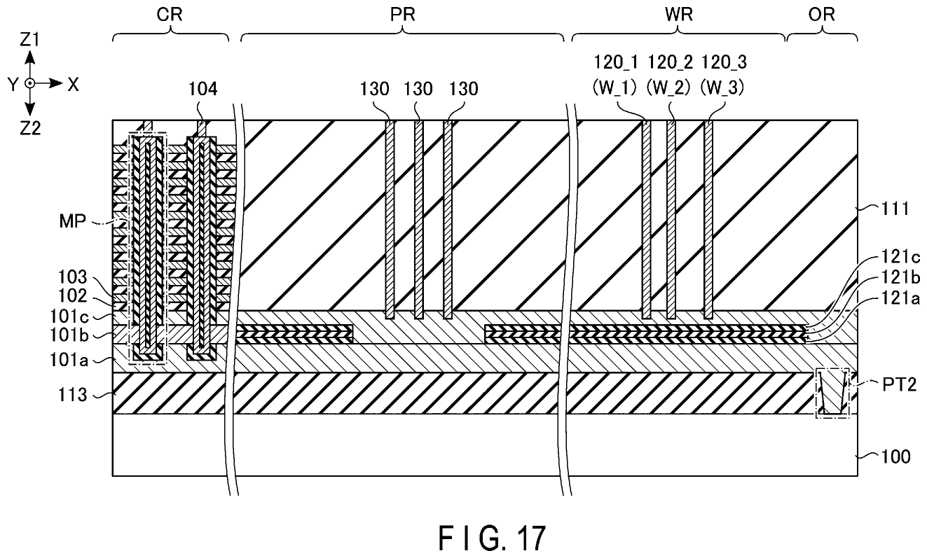

As shown in FIG. 17, the conductor 104 is formed on each memory pillar MP. In the peripheral circuit region PR, the conductors 130 are formed. In the wall region WR, the conductors 120_1 to 120_3 are formed. At this time, the bottom surfaces of the conductors 130 and the conductors 120_1 to 120_3 reach the film inside of the semiconductor layer 101c.

### 1.3 Manufacturing Method of Bonded Structure

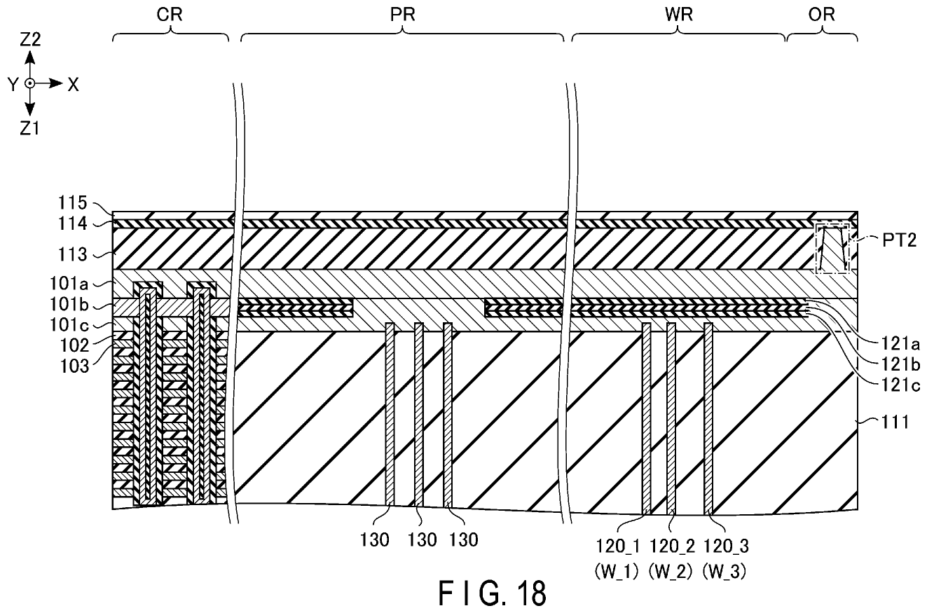

Next, an example of the manufacturing method of the bonded structure will be described with reference to FIG. 18 to FIG. 22. FIG. 18 to FIG. 22 are each a cross-sectional view showing an example of the manufacturing method of the bonded structure. The following description focuses on the process until formation of the interconnect layer 116.

As shown in FIG. 18, after the array chip 10 and the circuit chip 20 are bonded together, the semiconductor substrate 100 is removed by, for example, chemical mechanical polishing (CMP). Subsequently, the insulating layer 114 and the insulating layer 115 are formed on a surface facing in the Z2 direction of the insulating layer 113. Meanwhile, the purpose of forming the insulating layer 115 at this time is protection of the surface of the insulating layer 114, so that the thickness of the insulating layer 115 may be relatively thin.

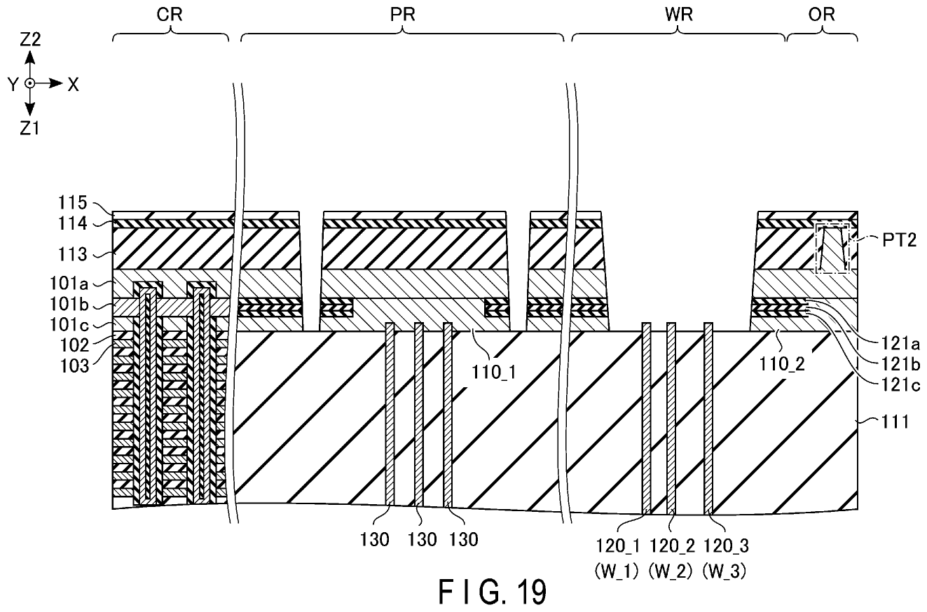

As shown in FIG. 19, the semiconductor layer 101 is separated. More specifically, trenches respectively corresponding to the protruding portions PT1a and PT1b are formed in the peripheral circuit region PR. That is, the insulating layer 115, the insulating layer 114, the insulating layer 113, the semiconductor layer 101a, the insulating layer 121, and the semiconductor layer 101c are processed. Bottom surfaces of the trenches reach the insulating layer 111. This results in formation of the semiconductor layer 101_1. Furthermore, a trench corresponding to the conductors 120_1 to 120_3 and their neighboring region is formed in the wall region WR. This results in formation of the semiconductor layer 101_2 in the outer peripheral region OR. In the bottom surface of the trench, the end portions in the Z2 direction of the conductors 120_1 to 120_3 are exposed.

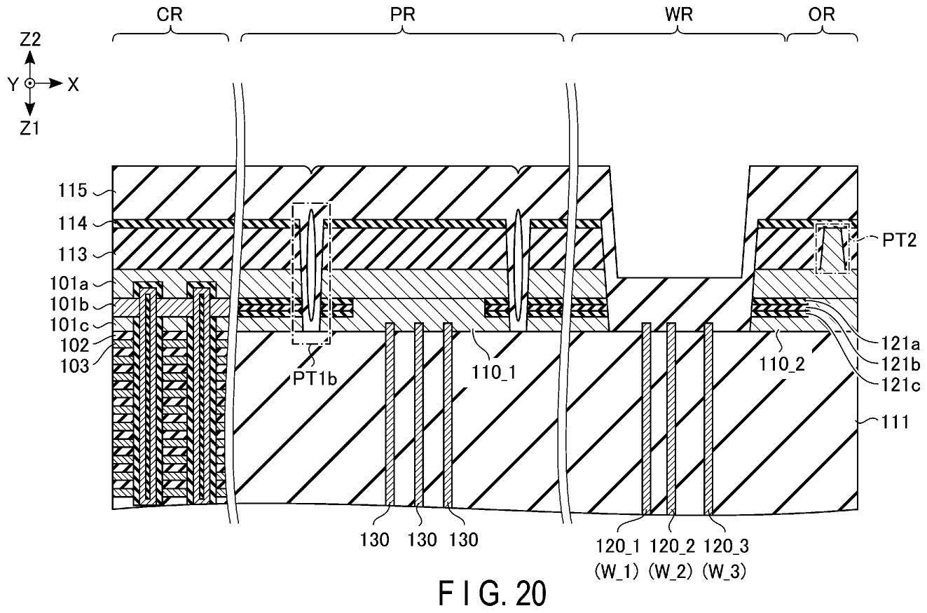

As shown in FIG. 20, the insulating layer 115 is formed. At this time, the thickness of the insulating layer 115 is set to be relatively thick in order to allow the protruding portion PT1b (and the protruding portion PT1a) to be embedded therein and a side wall to be formed on the side surface of the semiconductor layer 101 exposed on the side wall of the trench in the wall region WR.

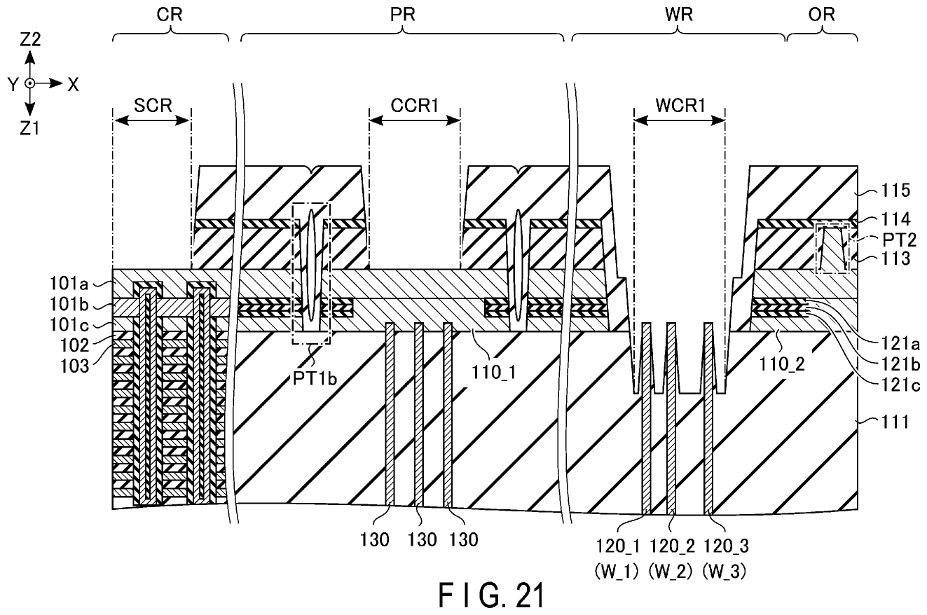

As shown in FIG. 21, the SL coupling region SCR, the CC connection region CCR1, and the wall connection region WCR1 are collectively processed. More specifically, the insulating layer 115, the insulating layer 114, and the insulating layer 113 are processed in the SL connection region SCR of the core region CR and the CC connection region CCR1 of the peripheral circuit region PR. This exposes the semiconductor layer 101a. At this time, the insulating layer 115 and the insulating layer 111 are processed in the wall connection region WCR1 of the wall region WR. This digs into the insulating layer 111 to expose the protruding portions of the conductors 120_1 to 120_3.

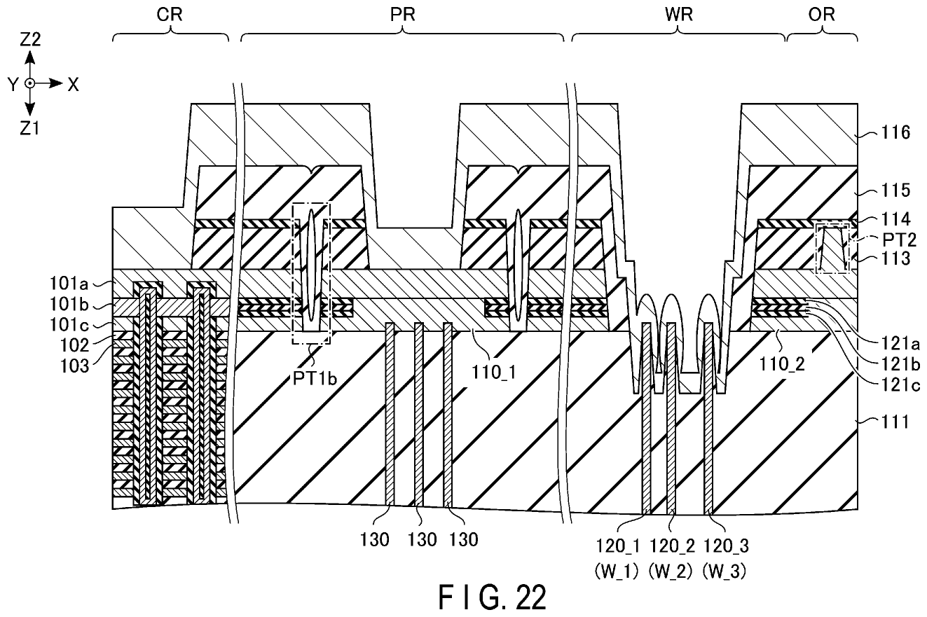

As shown in FIG. 22, the interconnect layer 116 is formed.

### 1.4 Advantageous Effect of Present Embodiment

The configuration according to the present embodiment can improve reliability of the semiconductor device 1. The advantageous effects will be described below.

For example, the conductors 120 protrude from the bottom surface of the trench of the insulating layer 111 in the connection portion between the conductors 120 and the interconnect layer 116. The interconnect layer 116 is formed in such a manner as to cover the protruding portions of the conductors 120. With such a configuration, the interconnect layer 116 decreases in thickness on the side surface and the root portion of the protruding portion of the conductor 120 because of the poor step coverage of the interconnect layer 116. This tendency becomes more apparent as the amount of protrusion in the protruding portion of the conductor 120 increases. In response to the interconnect layer 116 decreasing in film thickness, electromigration (EM) resistance become deteriorated. Thus, with the increase in the amount of current flowing through the interconnect layer 116, disconnection of the interconnect layer 116 is prone to occur. However, the conductors 120 are used to fix the outer periphery of the semiconductor device 1 at the same electric potential (ground potential VSS). In addition, since the conductors 120 are provided in such a manner as to surround the element region ER, a region in contact with the interconnect layer 116 is relatively wide. Therefore, the amount of current (density of current) flowing from the interconnect layer 116 to the conductors 120 are relatively small. In addition, by the conductor 120 being in contact with the interconnect layer 116, permeation of water from the chip end can be prevented. Thus, such a configuration is preferable. On the other hand, the interconnect layer 116 coupled to the conductor 130 is provided with an external connection terminal. Therefore, the amount of current flowing from the interconnect layer 116 to the conductor 130 (contact plug CC) is relatively large. Therefore, if a similar configuration is applied to the connection portion between the conductor 130 and the interconnect layer 116, there is a risk of decreasing reliability due to deterioration in EM resistance.

On the other hand, the configuration according to the present embodiment enables, in the peripheral circuit region OR, the interconnect layer 116 to be coupled to the conductor 130 via the semiconductor layer 101. This realizes a reduction in step in the interconnect layer 116 in the connection portion (CC connection region CCR1) of the interconnect layer 116. Furthermore, the interconnect layer 116 is in contact with the flat semiconductor layer 101. This can prevent a decrease in film thickness due to the poor step coverage of the interconnect layer 116. Thus, a reduction in reliability due to a decrease in film thickness of the interconnect layer 116 can be prevented.

Furthermore, the configuration according to the present embodiment can reduce the step in the interconnect layer 116 in the peripheral circuit region PR. This realizes a reduction in step in the surface in the Z2 direction of the semiconductor device 1. This can reduce, in a case of stacking a plurality of semiconductor devices 1, a risk of causing a void between the stacked semiconductor devices 1.

### 1.5 Modifications

Next, three modifications of the first embodiment will be described. Hereinafter, the matters different from the first embodiment will be mainly described.

### 1.5.1 First Modification

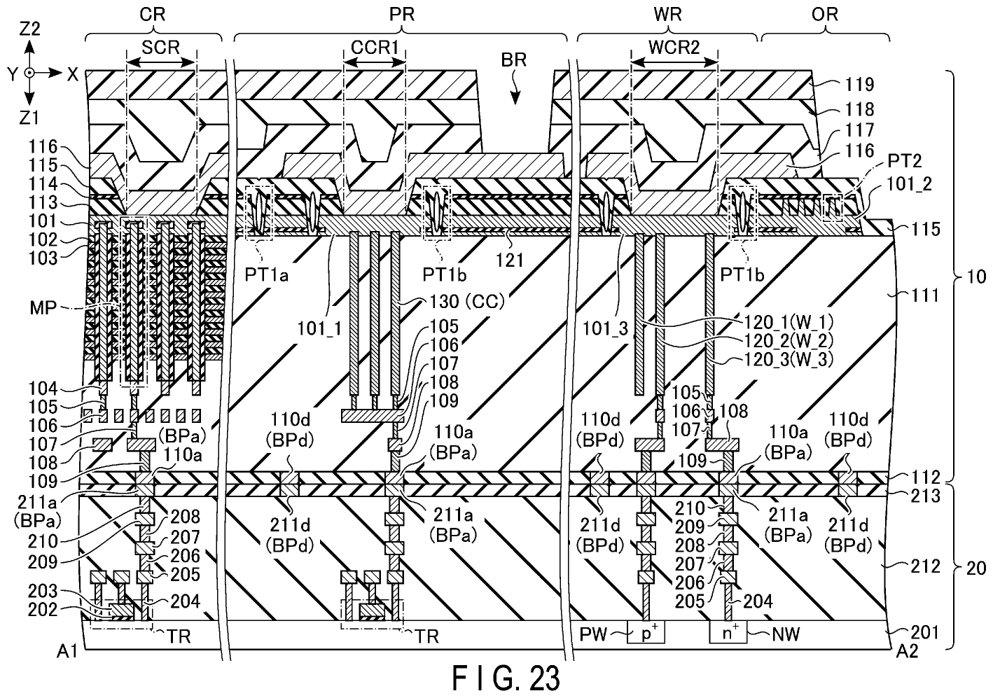

First, a first modification of the first embodiment will be described with reference to FIG. 23. FIG. 23 is a cross-sectional view showing an example of the cross-sectional structure of the semiconductor device 1.

As shown in FIG. 23, in the wall region WR in this example, as with the configuration of the CC connection region CCR1, the conductors 120_1 to 120_3 are electrically coupled to the interconnect layer 116 via the semiconductor layer 101.

The semiconductor layer 101 in contact with the interconnect layer 116 is separated by the protruding portion PT1b provided on the insulating layer 115, from the surrounding semiconductor layer 101. Hereinafter, in the wall region WR, the semiconductor layer 101 in a ring-shaped region, separated by the protruding portion PT1b, will be referred to as the semiconductor layer 101_3 in a case where it is distinguished from the remaining portions of the regions of semiconductor layer 101. Furthermore, a region in which the semiconductor layer 101_3 is coupled to the interconnect layer 116 will also be referred to as a “wall connection region WCR2”. The wall connection region WCR2 is a region in which the insulating layer 115, the insulating layer 114, and the insulating layer 113 above the semiconductor layer 101_3 are removed in the wall region WR. As viewed in the Z direction, at least a part of the semiconductor layer 101_3 is not provided with the insulating layer 121. By this, the conductors 120_1 to 120_3 are electrically coupled to the interconnect layer 116 via the semiconductor layer 101_3.

### 1.5.2 Second Modification

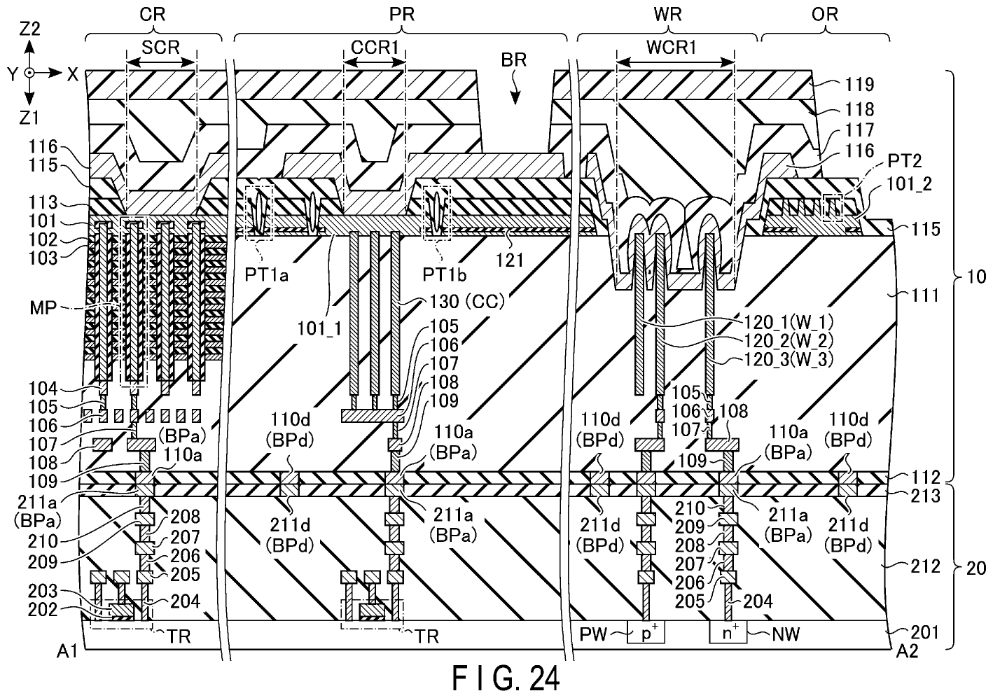

Next, a second modification of the first embodiment will be described with reference to FIG. 24. FIG. 24 is a cross-sectional view showing an example of the cross-sectional structure of the semiconductor device 1.

As shown in FIG. 24, this example eliminates the insulating layer 114 provided between the insulating layer 113 and the insulating layer 115 in FIG. 5 showing the first embodiment.

### 1.5.3 Third Modification

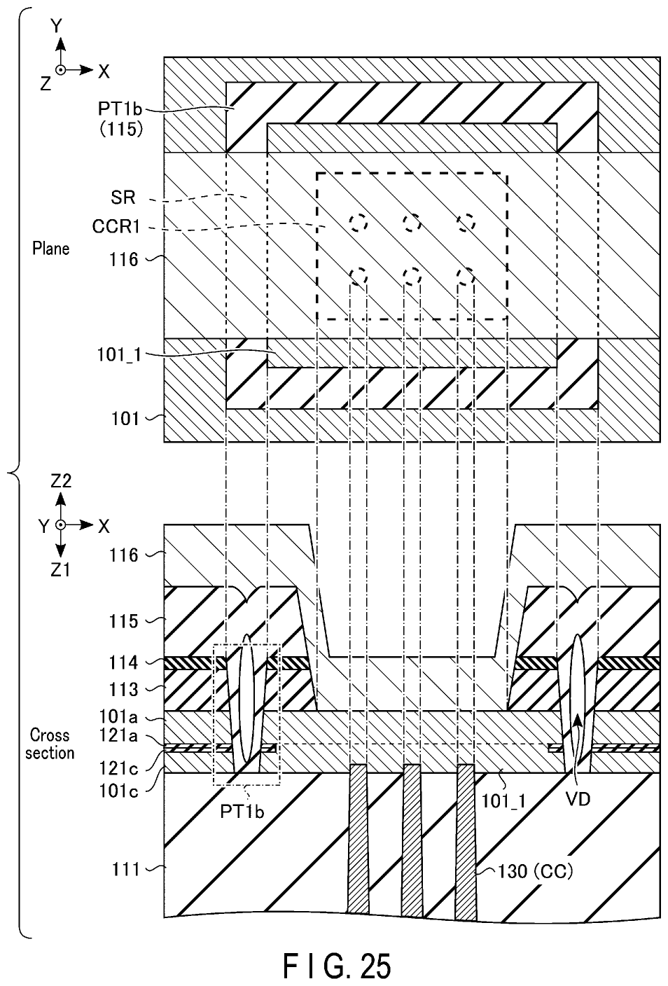

Next, a third modification of the first embodiment will be described with reference to FIG. 25. FIG. 25 is a plane view and a cross-sectional view of the CC connection region CCR1.

As shown in FIG. 25, this example eliminates the insulating layer 121b provided between the insulating layer 121a and the insulating layer 121c in FIG. 10 showing the first embodiment.

### 1.5.4 Advantageous Effect of Modifications

The configurations according to the first to third modifications of the first embodiment can attain the same effect as that of the first embodiment.

### 2. Second Embodiment

Next, the second embodiment will be described. The second embodiment will describe the semiconductor device 1 in terms of structural difference from the first embodiment. Hereinafter, points different from the first embodiment will be mainly described.

### 2.1 Cross-Sectional Structure of Semiconductor Device

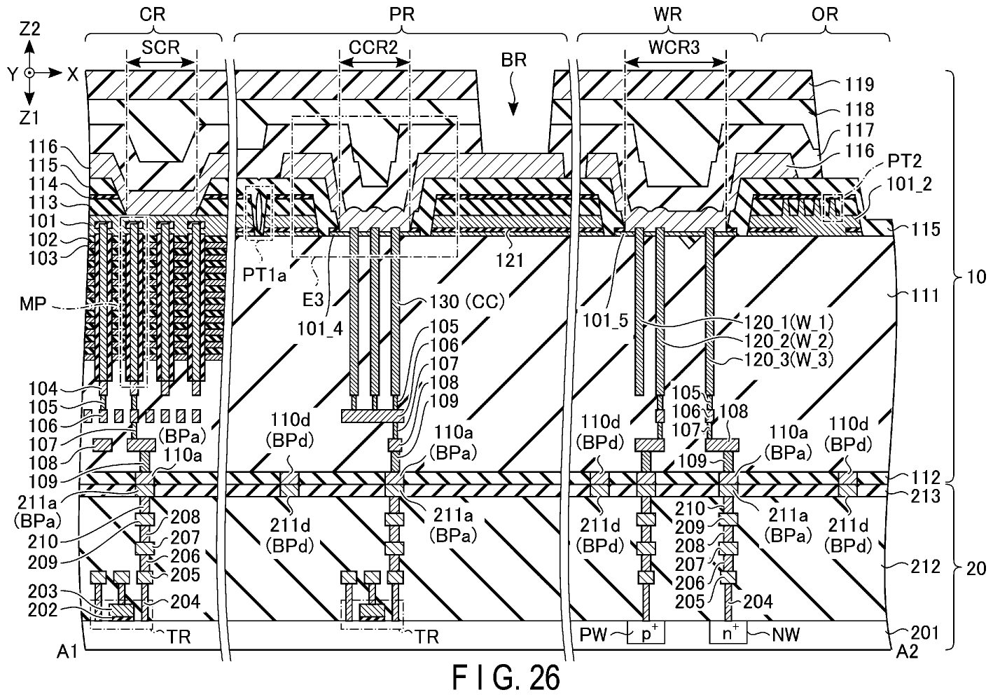

First, an example of the cross-sectional structure of the semiconductor device 1 will be described with reference to FIG. 26. FIG. 26 is a cross-sectional view showing an example of the cross-sectional structure of the semiconductor device 1. The example in FIG. 26 shows a cross section in the X direction taken along the line A1 to A2 shown in FIG. 4.

As shown in FIG. 26, the configurations of the core region CR and the outer peripheral region OR of the array chip 10 and the circuit chip 20 are similar to those of the first embodiment.

First, the peripheral circuit region PR of the array chip 10 will be described. In the present embodiment, the interconnect layer 116 provided with the external connection terminal is in contact with the semiconductor layer 101 (101c) and the plurality of conductors 130. In the example shown in FIG. 26, three conductors 130 are arranged side by side in the X direction. The conductors 130 penetrate the semiconductor layer 101 (101c). The end portions in the Z2 direction of the conductors 130 are in contact with the interconnect layer 116 provided with the external connection terminal.

The semiconductor layer 101 in contact with the interconnect layer 116 is separated by the insulating layer 115 from the surrounding semiconductor layer 101. Hereinafter, the separated semiconductor layer 101 will be referred to as a “semiconductor layer 101_4”. Furthermore, a region in which the interconnect layer 116 is coupled to the semiconductor layer 101_4 and the conductors 130 will also be referred to as a “CC connection region CCR2”. The CC connection region CCR2 is a region in which the insulating layer 115, the insulating layer 114, the insulating layer 113, the semiconductor layer 101a, and the insulating layer 121 are removed in the peripheral circuit region PR.

The connection of the end portions in the Z1 direction of the conductors 130 is similar to that of FIG. 5 showing the first embodiment.

Next, the wall region WR of the array chip 10 will be described. As with the peripheral circuit region PR, the interconnect layer 116 in the wall region WR is in contact with the semiconductor layer 101 (101c) and the conductors 120_1 to 120_3. The conductors 120_1 to 120_3 penetrate the semiconductor layer 101 (101c). The end portions in the Z2 direction of the conductors 120_1 to 120_3 are in contact with the interconnect layer 116.

The semiconductor layer 101 in contact with the interconnect layer 116 is separated by the insulating layer 115 from the surrounding semiconductor layer 101. Hereinafter, the separated semiconductor layer 101 will be referred to as a “semiconductor layer 101_5”. Furthermore, a region in which the interconnect layer 116 is coupled to the semiconductor layer 101_5 and the conductors 120_1 120_3 will also be referred to as a “wall connection region WCR3”. The wall connection region WCR3 is a region in which the insulating layer 115, the insulating layer 114, the insulating layer 113, the semiconductor layer 101a, and the insulating layer 121 are removed in the wall region WR.

The connection of the end portions in the Z1 direction of the conductors 120_1 120_3 is similar to that of FIG. 5 showing the first embodiment.

### 2.2 Configuration of CC Connection Region

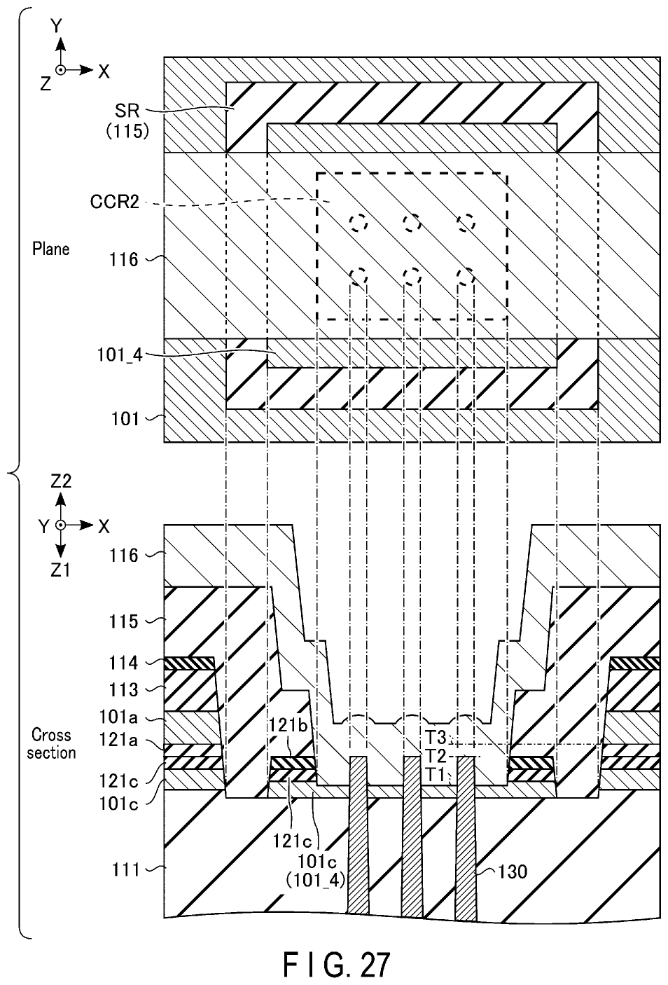

Next, an example of the structure of the CC connection region CCR2 will be described with reference to FIG. 27. FIG. 27 shows a plane view and a cross-sectional view of a region E3 shown in FIG. 26. The plane view of FIG. 27 omits layers other than the semiconductor layers 101 and 101_4, the insulating layer 115 functioning as the separation region SR, and the interconnect layer 116. In addition, the cross-sectional view of FIG. 27 omits the insulating layers 117 and 118 and the surface protective layer 119 on the surface facing in the Z2 direction of the interconnect layer 116. Meanwhile, the configuration of the wall connection region WCR3 is similar to that in a case in which the conductors 130 are replaced with the conductors 120_1 to 120_3.

As shown in the plane view of FIG. 27, the insulating layer 115 forms the separation region SR in a square ring shape. The separation region SR separates the semiconductor layer 101_4 from the remaining portions of the semiconductor layer 101. In the CC connection region CCR2, the surface facing in the Z2 direction of the semiconductor layer 101_4 and the plurality of the conductors 130 are in contact with the interconnect layer 116. In the example shown in FIG. 27, six conductors 130 are in contact with the single interconnect layer 116.

As shown in the cross-sectional view in FIG. 27, the semiconductor layer 101 excluding the semiconductor layer 101_4 in the peripheral circuit region PR includes two semiconductor layers 101a and 101c, and does not include the semiconductor layer 101b. In the semiconductor layer 101 in the peripheral circuit region PR (the region excluding the semiconductor layer 101_4), the insulating layers 121a and 121c are provided between the semiconductor layer 101a and the semiconductor layer 101c. That is, the insulating layer 121b is not provided.

The semiconductor layer 101_4 corresponds to the semiconductor layer 101c. The semiconductor layer 101_4 does not include the semiconductor layer 101a and the semiconductor layer 101b. In the region excluding the CC connection region CCR2 of the semiconductor layer 101_4, the insulating layers 121b and 121c are provided on the surface facing in the Z2 direction of the semiconductor layer 101c. The insulating layer 121b and 121c may not remain.

In the separation region SR, a square ring shape of the insulating layer 114, the insulating layer 113, the semiconductor layer 101a, the insulating layers 121a to 121c, and the semiconductor layer 101c is removed. In a region excluding the CC connection region CCR2 of the semiconductor layer 101_4, the insulating layer 114, the insulating layer 113, the semiconductor layer 101a, and the insulating layer 121a are removed. The insulating layer 115 is provided in such a manner as to cover the upper surface of the insulating layer 114, the side surfaces of the insulating layer 114, the insulating layer 113, the semiconductor layer 101a, the insulating layer 121a, the insulating layer 121c, and the semiconductor layer 101c, and the upper surface of the insulating layer 121b above the semiconductor layer 101_4. The insulating layer 115 in contact with the side surfaces of the insulating layer 114, the insulating layer 113, the semiconductor layer 101a, the insulating layer 121a, the insulating layer 121c, and the semiconductor layer 101c functions as the separation region SR. In the separation region SR, the insulating layer 115 is in contact with the insulating layer 111.

In the CC connection region CCR2, the insulating layer 115, the insulating layer 121b, and the insulating layer 121c above the semiconductor layer 101_4 (101c) are removed. The end portions in the Z2 direction of the conductors 130 penetrate the semiconductor layer 101_4 to protrude in the Z2 direction. The interconnect layer 116 is provided in such a manner as to cover the semiconductor layer 101_4 and the protruding portions of the conductors 130 in the CC connection region CCR2. That is, the interconnect layer 116 is in contact with the conductors 130.

The height position in the Z2 direction of the surface facing in the Z2 direction of the semiconductor layer 101_4, that is, the semiconductor layer 101c, will be referred to as T1. The height position in the Z2 direction of the end portions in the Z2 direction of the conductors 130 will be referred to as T2. The height position in the Z2 direction of the surface facing in the Z1 direction of the semiconductor layer 101a will be referred to as T3. In this case, the height positions T1, T2, and T3 satisfy the relation of T1<T2<T3. In other words, in the Z direction, the end portions in the Z2 direction of the conductors 130 are positioned between the pair of the semiconductor layer 101a and the semiconductor layer 101c.

### 2.3 Manufacturing Method of Array Chip

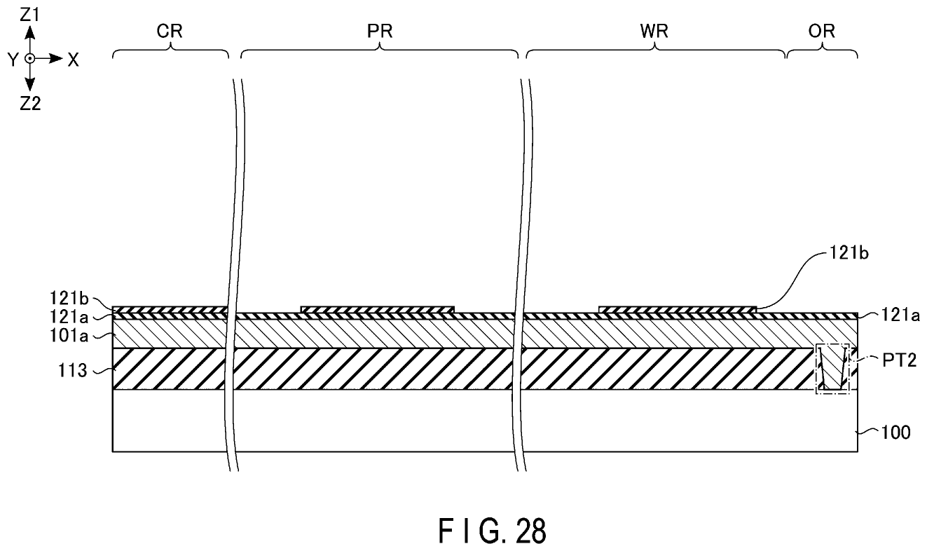

Next, an example of the manufacturing method of the array chip 10 will be described with reference to FIG. 28 to FIG. 33. FIG. 28 to FIG. 33 are each a cross-sectional view showing an example of a manufacturing process of the array chip 10. The following description focuses on the process until formation of the conductor 130.

As shown in FIG. 28, the insulating layer 113 is formed on the semiconductor substrate 100 of the array chip 10. A region (trench) corresponding to the protruding portion PT2 is formed by processing the insulating layer 113. Thereafter, the semiconductor layer 101a is formed. At this time, a region (trench) corresponding to a protruding portion PT2 is also filled in to thereby form the protruding portion PT2. This protruding portion PT2 is in contact with the semiconductor substrate 100. The insulating layers 121a and 121b are formed on the semiconductor layer 101a. Thereafter, the insulating layer 121b in the remaining region other than the memory cell array 11, a region corresponding to the semiconductor layer 101_4, and a region corresponding to the semiconductor layer 101_5 is removed.

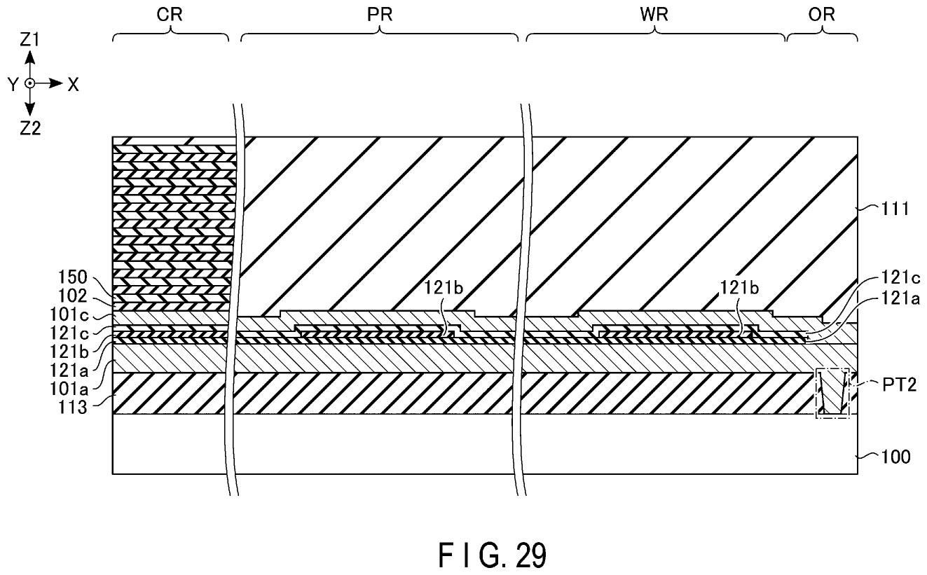

As shown in FIG. 29, the insulating layer 121c is formed on the insulating layers 121a and 121b. The insulating layers 121a and 121c in a region corresponding to the semiconductor layer 101_2 (that is, the neighboring region of the protruding portion PT2) are removed. Thereafter, the semiconductor layer 101c is formed. In the neighboring region of the protruding portion PT2, the semiconductor layer 101a and the semiconductor layer 101c are in contact with each other. Subsequently, in the core region CR, the plurality of insulating layers 102 and the plurality of sacrifice layers 150 are alternately stacked one by one. Thereafter, the insulating layer 111 is formed in such a manner as to cover the entire surface facing in the Z1 direction of the semiconductor substrate 100.

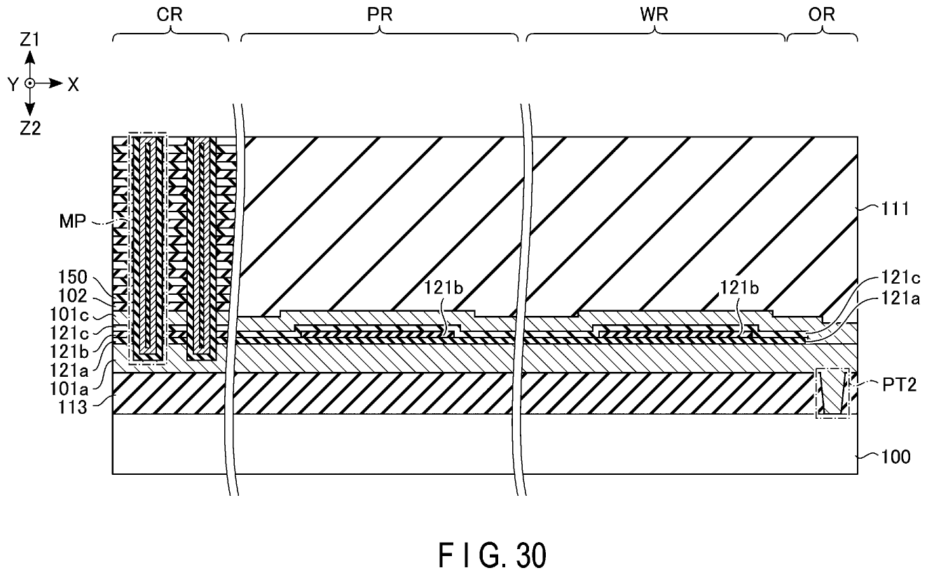

As shown in FIG. 30, the memory pillars MP are formed in the memory cell array 11 in the core region CR, as described with reference to FIG. 14 showing the first embodiment.

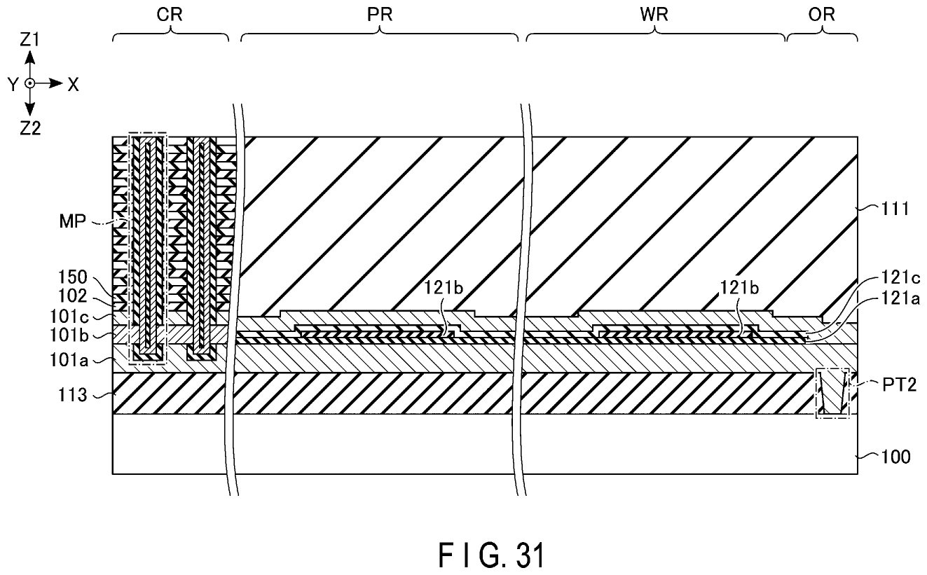

As shown in FIG. 31, the insulating layer 121, and the block insulating film 140, the charge storage film 141, and the tunnel insulating film 142 each having the periphery surrounded by the insulating layer 121 are replaced with the semiconductor layer 101b, as described with reference to FIG. 15 showing the first embodiment.

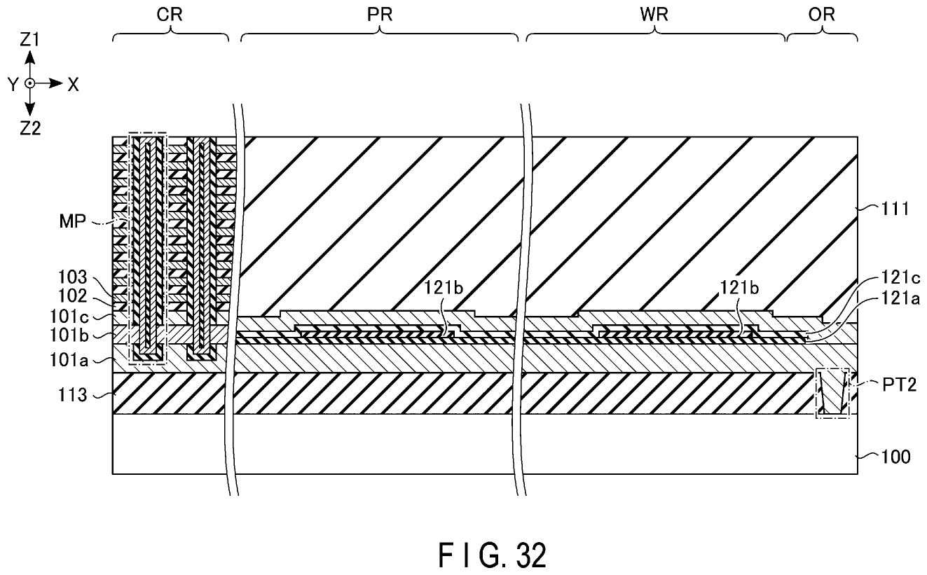

As shown in FIG. 32, the sacrifice layers 150 are replaced with the interconnect layers 103, as described with reference to FIG. 16 showing the first embodiment.

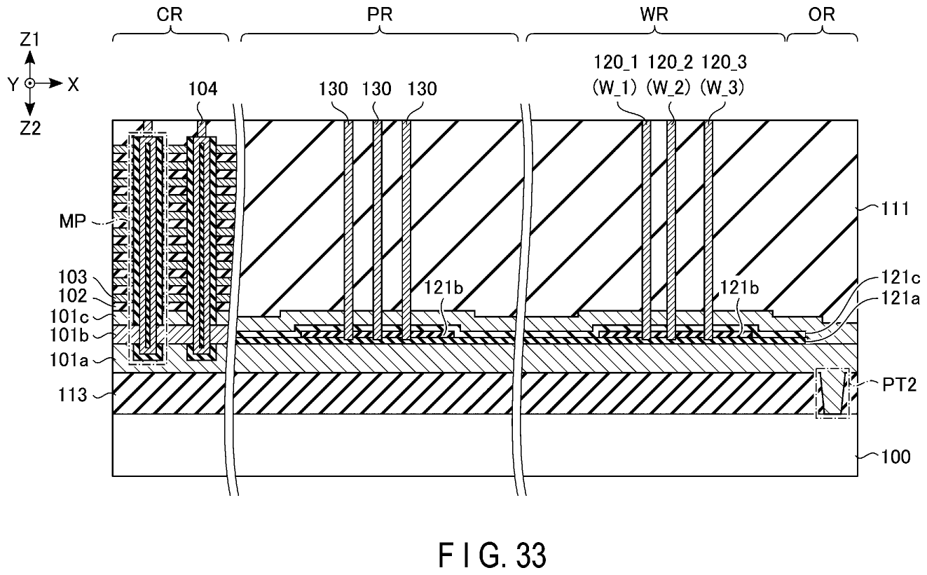

As shown in FIG. 33, the conductor 104 is formed on each memory pillar MP, as described with reference to FIG. 17 showing the first embodiment. The conductors 130 are formed in the peripheral circuit region PR. In the wall region WR, the conductors 120_1 to 120_3 are formed. At the time of processing a pattern corresponding to the conductors 130 and the conductors 120_1 to 120_3, the insulating layer 121b is used as an etching stopper. For example, the bottom surfaces of the conductors 130 and the conductors 120_1 to 120_3 penetrate the semiconductor layer 101c, the insulating layer 121c, and the insulating layer 121b to reach the insulating layer 121a. The bottom surfaces of the conductors 130 and the conductors 120_1 to 120_3 may be inside a film of the insulating layer 121b. In other words, in the Z direction, the end portions in the Z2 direction of the conductors 130 and the conductors 120_1 to 120_3 are positioned between the semiconductor layer 101a and the semiconductor layer 101c.

### 2.4 Manufacturing Method of Bonded Structure

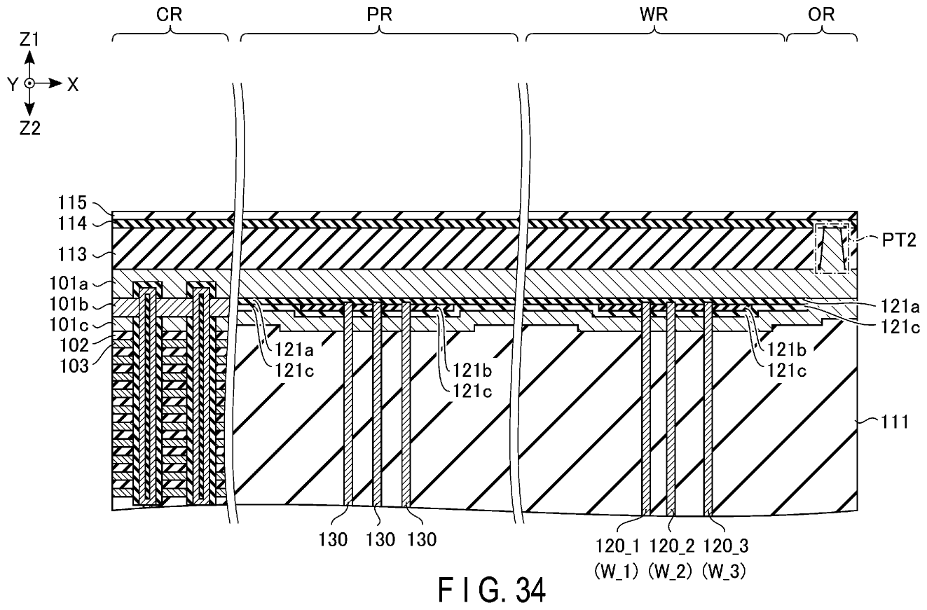

Next, an example of the manufacturing method of the bonded structure will be described with reference to FIG. 34 to FIG. 38. FIG. 34 to FIG. 38 are each a cross-sectional view showing an example of the manufacturing method of the bonded structure. The following description focuses on the process until formation of the interconnect layer 116.

As shown in FIG. 34, after the array chip 10 and the circuit chip 20 are bonded together, the semiconductor substrate 100 is removed by, for example, CMP. Subsequently, the insulating layer 114 and the insulating layer 115 are formed on a surface facing in the Z2 direction of the insulating layer 113. Meanwhile, the purpose of forming the insulating layer 115 at this time is protection of the surface of the insulating layer 114, so that the thickness of the insulating layer 115 may be relatively thin.

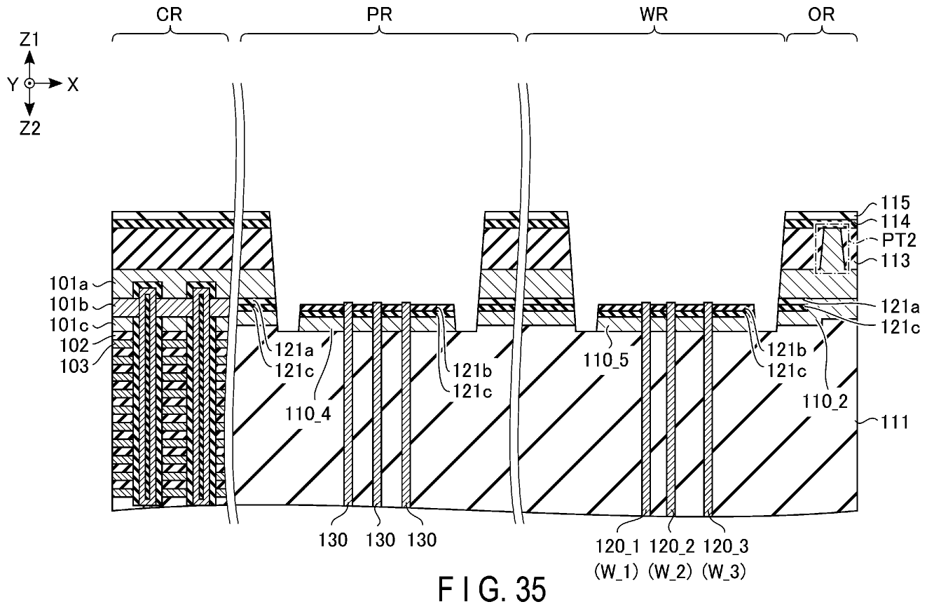

As shown in FIG. 35, the semiconductor layer 101 is separated. More specifically, in the peripheral circuit region PR and the wall region WR, the insulating layer 115, the insulating layer 114, the insulating layer 113, the semiconductor layer 101a, the insulating layer 121a, the insulating layer 121c, and the semiconductor layer 101c in the separation region SR and the inner region of the separation region SR are processed. At this time, the insulating layer 121b functions as an etching stopper in a region corresponding to the semiconductor layers 101_4 and 101_5. Therefore, the semiconductor layers 101_4 and 101_5 and the insulating layers 121b and 121c thereon remain without being removed. As long as the semiconductor layers 101_4 and 101_5, that is, the semiconductor layer 101c, remain, the insulating layers 121b and 121c thereon may be removed.

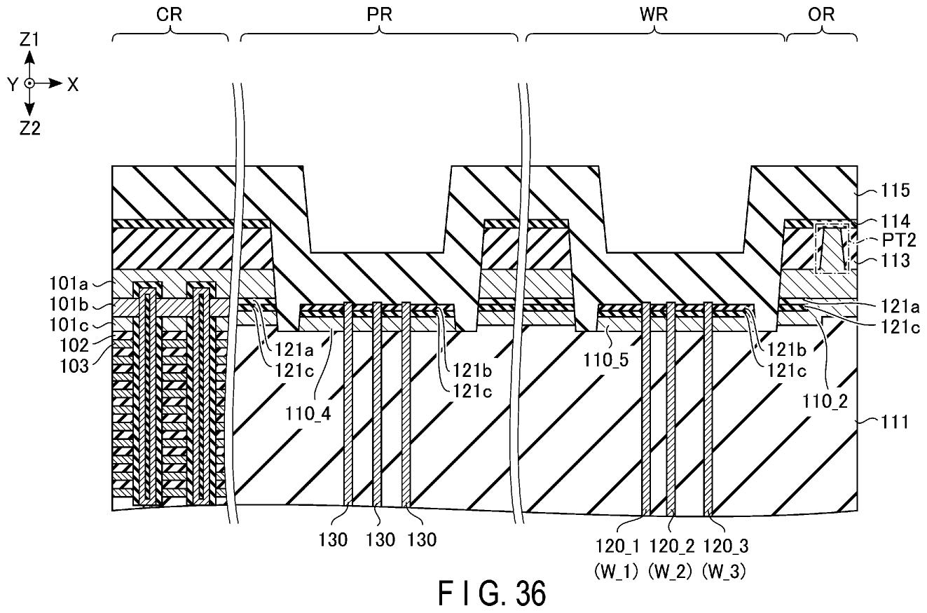

As shown in FIG. 36, the insulating layer 115 is formed. At this time, the thickness of the insulating layer 115 is set to be relatively thick in order to allow the separation region SR to be embedded therein.

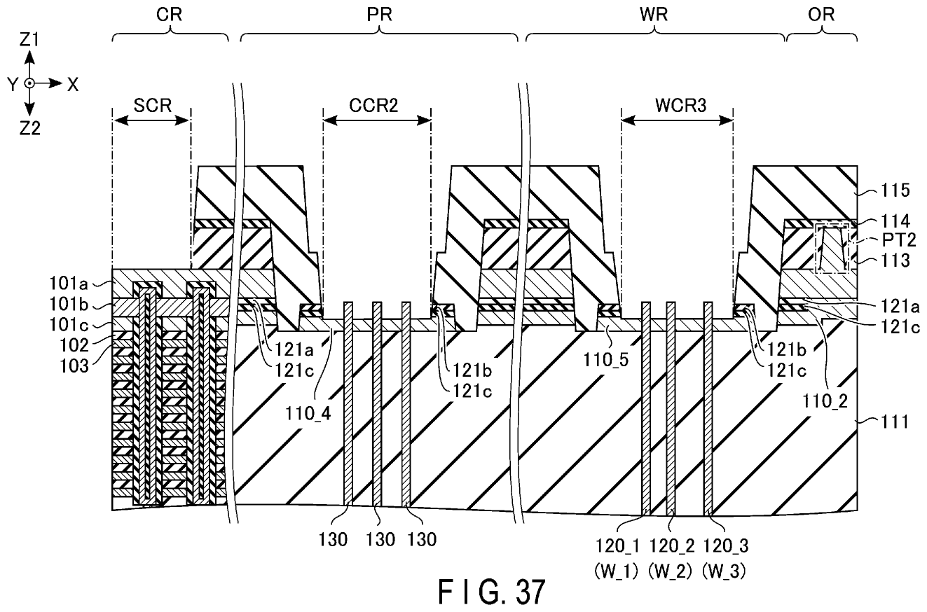

As shown in FIG. 37, the SL coupling region SCR, the CC connection region CCR2, and the wall connection region WCR3 are collectively processed. More specifically, the insulating layer 115, the insulating layer 114, and the insulating layer 113 are processed in the SL connection region SCR of the core region CR. This exposes the semiconductor layer 101a in the SL connection region SCR. Furthermore, the insulating layer 115 and the insulating layers 121b and 121c are processed in the CC connection region CCR2 of the peripheral circuit region PR and the wall connection region WCR3 of the wall region WR. At this time, the semiconductor layer 101c functions as an etching stopper. Accordingly, the insulating layer 111 can be prevented from being processed. This exposes the semiconductor layer 101_4 and the conductors 130 in the CC connection region CCR2. Furthermore, the semiconductor layer 101_5 and the conductors 120_1 to 120_3 are exposed in the wall connection region WCR3.

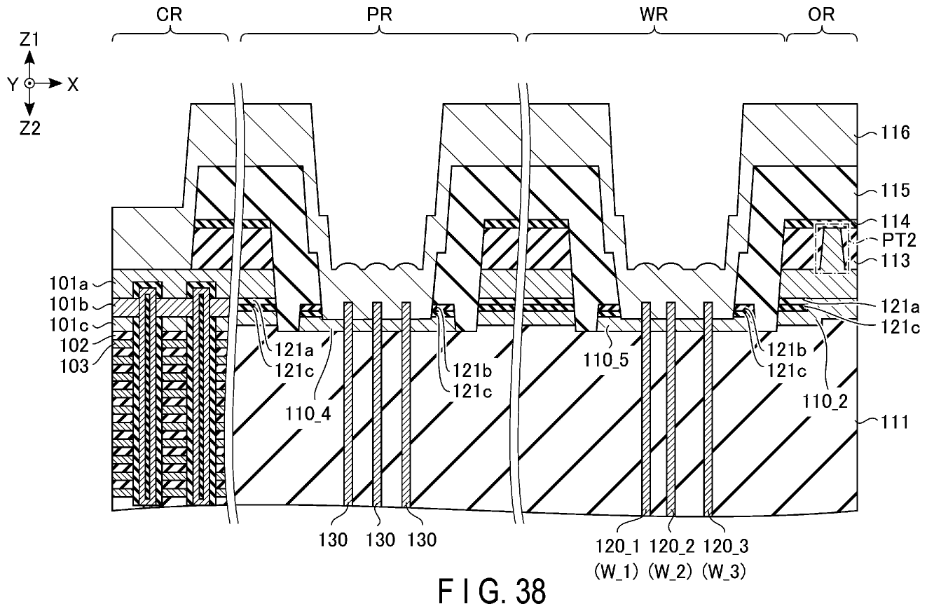

As shown in FIG. 38, the interconnect layer 116 is formed. The interconnect layer 116 is in contact with the conductors 130 exposed from the semiconductor layer 101_4 and the conductors 120_1 to 120_3 exposed from the semiconductor layer 101_5.

### 2.5 Advantageous Effect of Present Embodiment

The configuration of the present embodiment can attain the same effect as the first embodiment.

Specifically, the configuration according to the present embodiment can prevent etching of the insulating layer 111 by using the semiconductor layer 101c as an etching stopper in the processing of the CC connection region CCR2. By this, the amount of protrusion of the conductors 130 from the semiconductor layer 101_4 (101c) can be reduced. The step in the interconnect layer 116 can also be reduced. This can prevent a decrease in film thickness due to the poor step coverage of the interconnect layer 116. Thus, a reduction in reliability due to a decrease in film thickness of the interconnect layer 116 can be prevented.

Furthermore, the configuration according to the present embodiment can reduce the step in the interconnect layer 116 in the peripheral circuit region PR. This realizes a reduction in step in the surface in the Z2 direction of the semiconductor device 1. This can reduce, in a case of stacking a plurality of semiconductor devices 1, a risk of causing a void between the stacked semiconductor devices 1.

Furthermore, with the configuration according to the present embodiment, at the time of processing patterns (holes) corresponding to the conductors 130, the insulating layer 121b can be used as an etching stopper. Therefore, the end portions in the Z2 direction of the conductors 130 can be provided between the semiconductor layers 101a and 101c. This allows the end portions in the Z2 direction of the conductors 130 to be exposed after processing the CC connection region CCR2. This brings the conductors 130 in contact with the interconnect layer 116. This can suppress an increase in resistance value in a path that provides connection between the conductors 130 and the interconnect layer 116.

### 2.6 Modifications

Next, two modifications of the second embodiment will be described. Hereinafter, points different from the second embodiment will be mainly described.

### 2.6.1 First Modification

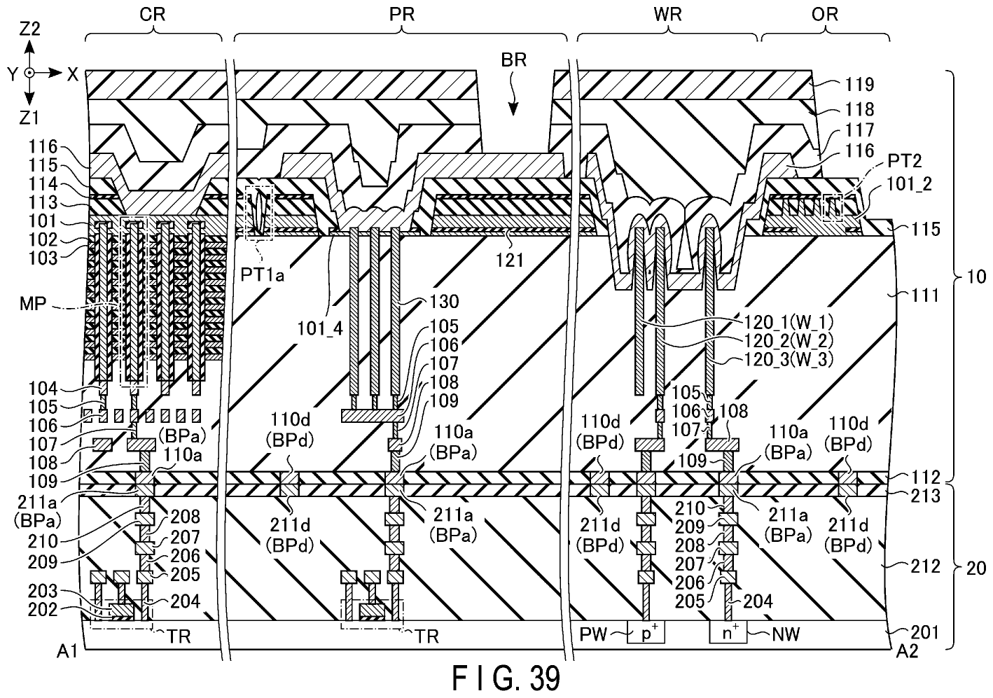

First, a first modification of the second embodiment will be described with reference to FIG. 39. FIG. 39 is a cross-sectional view showing an example of the cross-sectional structure of the semiconductor device 1.

As shown in FIG. 39, in this modification, the end portions in the Z2 direction of the conductors 120_1 to 120_3 protrude from the dug surface of the insulating layer 111, as with the configuration of the wall connection region WCR1 according to the first embodiment. The interconnect layer 116 is formed in such a manner as to cover the end portions of the conductors 120_1 to 120_3 protruding in the Z2 direction.

### 2.6.2 Second Modification

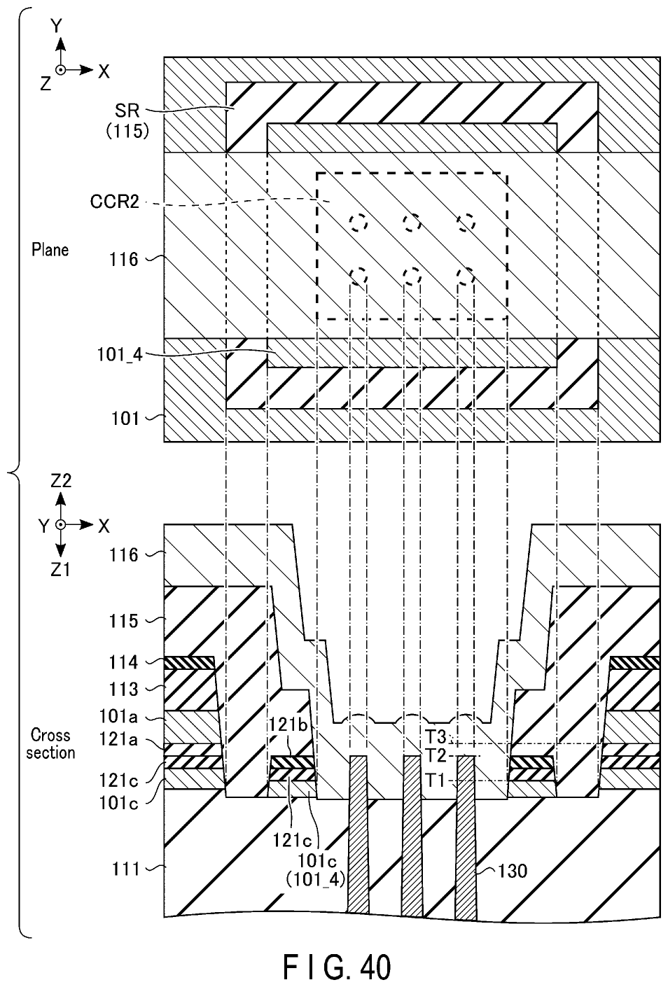

Next, a second modification of the second embodiment will be described with reference to FIG. 40. FIG. 40 is a plane view and a cross-sectional view of the CC connection region CCR2.

As shown in FIG. 40, in this modification, the semiconductor layer 101_4 (101c) is removed from the CC connection region CCR2. In the CC connection region CCR2, the interconnect layer 116 penetrates the semiconductor layer 101_4 (101c) to come into contact with the insulating layer 111. Such a configuration may be formed in a case where, for example, the semiconductor layer 101c serving as an etching stopper does not remain at the time of processing the CC connection region CCR2.

### 2.6.3 Advantageous Effect of Modifications

The configurations of the first and second modifications of the second embodiment can attain the same effect as the second embodiment.

### 3. Modifications, Etc.

According to the above embodiment, the semiconductor device (1) includes a first chip (20) including a substrate (201) and a second chip (10) bonded to the first chip. The second chip includes a first interconnect layer (116) provided with an external connection terminal, a first semiconductor layer (101_1) in contact with the first interconnect layer, and a conductor (130) extending in a first direction (Z direction), having an end portion in contact with the first semiconductor layer, and electrically coupled to the first chip.

The semiconductor device 1 can be improved in reliability by applying the above embodiments.

The embodiments are not limited to the above-described aspect, and can be modified in various ways.

Furthermore, the term “couple” in the above-described embodiments also includes the state of indirect coupling with other components, such as a transistor and a resistor, interposed therebetween.

Furthermore, the term “identical layer” in the above-described embodiments include layers even with a difference in height in the Z direction due to a step in a foundation as long as they are formed through the same process.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first chip including a substrate; and
a second chip bonded to the first chip,
wherein the second chip includes:
a first interconnect layer provided with an external connection terminal;
a first semiconductor layer in contact with the first interconnect layer; and
a conductor extending in a first direction, having an end portion in contact with the first semiconductor layer, and electrically coupled to the first chip.

2. The semiconductor device according to claim 1, wherein the first semiconductor layer includes:
a lower semiconductor layer in contact with the conductor; and
an upper semiconductor layer provided on the lower semiconductor layer and being in contact with the first interconnect layer.

3. The semiconductor device according to claim 1, wherein the second chip further includes:
a second semiconductor layer provided at least partially in an identical layer to the first semiconductor layer and electrically insulated from the first semiconductor layer;
a plurality of second interconnect layers stacked apart in the first direction between the second semiconductor layer and the first chip; and
a memory pillar extending in the first direction, passing through the plurality of second interconnect layers, and having an end portion in contact with the second semiconductor layer.

4. The semiconductor device according to claim 1, wherein the second chip further includes:
a third semiconductor layer provided in an identical layer to the first semiconductor layer and electrically insulted from the first semiconductor layer;
a separation insulating layer provided between the first semiconductor layer and the third semiconductor layer and surrounding the first semiconductor layer; and
an intermediate insulating layer provided inside the third semiconductor layer.

5. The semiconductor device according to claim 1, wherein the first chip includes a first pad provided on a bonding surface with the second chip, and
the second chip further includes a second pad provided on the bonding surface, electrically coupled to the conductor, and being in contact with the first pad.

6. The semiconductor device according to claim 2, wherein the second chip further includes an intermediate insulating layer provided between a part of the lower semiconductor layer and a part of the upper semiconductor layer.

7. The semiconductor device according to claim 6, wherein the intermediate insulating layer includes:
a pair of first insulating layers provided on a lower layer side and an upper layer side; and
a second insulating layer provided between the first insulating layers forming the pair and being different in composition from the pair of first insulating layers.

8. The semiconductor device according to claim 3, wherein the second chip further includes:
a third interconnect layer provided in an identical layer to the first interconnect layer, electrically insulated from the first interconnect layer, and being in contact with the second semiconductor layer; and
an interlayer insulating layer provided between the third interconnect layer and the second semiconductor layer in a region in which the third interconnect layer and the second semiconductor layer are not in contact with each other.

9. The semiconductor device according to claim 3, wherein the memory pillar includes:
a fourth semiconductor layer extending in the first direction and coupled to the second semiconductor layer; and
a charge storage film provided between the plurality of second interconnect layers and the fourth semiconductor layer.

10. The semiconductor device according to claim 4, wherein the separation insulating layer includes a void.

11. A semiconductor device comprising:
a first chip including a substrate; and
a second chip bonded to the first chip,
wherein the second chip includes:
a first interconnect layer provided with an external connection terminal;
a first semiconductor layer in contact with the first interconnect layer; and
a conductor extending in a first direction, passing through the first semiconductor layer in a region in which the first interconnect layer and the first semiconductor layer are in contact with each other, having an end portion in contact with the first interconnect layer, and electrically coupled to the first chip.

12. The semiconductor device according to claim 11, wherein the second chip further includes:
a second semiconductor layer provided at least partially in an identical layer to the first semiconductor layer and electrically insulated from the first semiconductor layer;
a plurality of second interconnect layers stacked apart in the first direction between the second semiconductor layer and the first chip; and
a memory pillar extending in the first direction, passing through the plurality of second interconnect layers, and having an end portion in contact with the second semiconductor layer.

13. The semiconductor device according to claim 11, wherein the second chip further includes:
a lower semiconductor layer provided in an identical layer to the first semiconductor layer and electrically insulated from the first semiconductor layer;
a separation insulating layer provided between the first semiconductor layer and the lower semiconductor layer and surrounding the first semiconductor layer;
a first insulating layer provided on the lower semiconductor layer;
an upper semiconductor layer provided on the first insulating layer; and
a second insulating layer provided above the first semiconductor layer in a region in which the first interconnect layer and the first semiconductor layer are not in contact with each other, and being different in composition from the first insulating layer.

14. The semiconductor device according to claim 13, wherein the separation insulating layer is further provided between the first interconnect layer and the second insulating layer.

15. The semiconductor device according to claim 11, wherein the first chip includes a first pad provided on a bonding surface with the second chip, and
the second chip further includes a second pad provided on the bonding surface, electrically coupled to the conductor, and being in contact with the first pad.

16. A semiconductor device comprising:
a first chip including a substrate; and
a second chip bonded to the first chip,
wherein the second chip includes:
a pair of semiconductor layers provided apart from each other in a first direction;
a first insulating layer provided between the semiconductor layers forming the pair;
a conductor extending in the first direction, having an end portion in the first direction with a height position placed between the semiconductor layers forming the pair, and electrically coupled to the first chip; and
a first interconnect layer in contact with the end portion of the conductor, the first interconnect layer being provided with an external connection terminal.

17. The semiconductor device according to claim 16, wherein the second chip further includes:
a first semiconductor layer provided in an identical layer to a semiconductor layer that is included in the pair of semiconductor layers and is provided on a side closer to the first chip, the first semiconductor layer being electrically insulated from the pair of semiconductor layers; and
a separation insulating layer provided between the first semiconductor layer and the semiconductor layer that is included in the pair of semiconductor layers and is provided on the side closer to the first chip, the separation insulating layer surrounding the first semiconductor layer.

18. The semiconductor device according to claim 17, wherein the first interconnect layer passes through the first semiconductor layer in the first direction in a region in which the first interconnect layer and the end portion of the conductor are in contact with each other.

19. The semiconductor device according to claim 16, wherein the second chip further includes:
a second semiconductor layer including a lower semiconductor layer, an upper semiconductor layer, and an intermediate semiconductor layer, and electrically insulated from the pair of semiconductor layers, the lower semiconductor layer and the upper semiconductor layer being respectively provided in identical layers to the semiconductor layers forming the pair, the intermediate semiconductor layer being provided between the lower semiconductor layer and the upper semiconductor layer;
a plurality of second interconnect layers stacked apart in the first direction between the second semiconductor layer and the first chip; and
a memory pillar extending in the first direction, passing through the plurality of second interconnect layers, and having an end portion in contact with the second semiconductor layer.

20. The semiconductor device according to claim 16, wherein the first chip includes a first pad provided on a bonding surface with the second chip, and
the second chip further includes a second pad provided on the bonding surface, electrically coupled to the conductor, and being in contact with the first pad.
